(19) United States
(12) Patent Application Publication
(10) Pub. No.: US 2021/0231889 A1
(43) Pub. Date: Jul. 29, 2021

(54) OPTICAL ARRAYS, FILTER ARRAYS, OPTICAL DEVICES AND METHOD OF FABRICATING SAME

(71) Applicant: Attonics Systems Pte Ltd, Singapore (SG)

(72) Inventors: Sascha Pierre Heussler, Singapore (SG); Shuvan Prashant Turaga, Singapore (SG); Sri Harsha Kasi Raj, Singapore (SG); Herbert Oskar Moser, Karlsruhe (DE); Erich Pantele, Murnau (DE)

(21) Appl. No.: 17/140,557

(22) Filed: Jan. 4, 2021

Related U.S. Application Data
(60) Provisional application No. 62/957,632, filed on Jan. 6, 2020.

(51) Int. Cl. G02B 6/42; G02B 6/12; G02B 6/13

(52) U.S. Cl. CPC G02B 6/4249; G02B 6/13; G02B 6/12011

(57) ABSTRACT

Disclosed are optical arrays and optical devices that can be operated in narrow and wide spectral bands and at high spectral resolutions. Disclosed also are filter arrays with replicated etalon units that can function as bandpass filters. Disclosed further are methods for manufacturing optical arrays, filter arrays, and optical devices having such optical or filter arrays.

### CROSS-REFERENCE TO RELATED APPLICATION

This application claims priority to U.S. Provisional Application No. 62/957,632 filed Jan. 6, 2020, the entire contents of which is incorporated herein for all purposes by this reference.

### TECHNICAL FIELD

The present application relates generally to optical arrays, optical devices and methods of fabricating such optical arrays and devices. More particularly, the present application relates to large etalon arrays, filter arrays having replicated etalon units, optical devices having such etalon arrays or filter arrays, and methods of fabricating such arrays and devices.

### BACKGROUND

Fabry-Perot or etalon arrays are widely used in spectroscopic devices. In many cases, a spectroscopic device is formed by stacking an etalon array on top of a detector array such as a charge-coupled device (CCD) or a complementary metal-oxide semiconductor (CMOS).

For instance, CN 101476936 B discloses a spectrometer comprising a Fabry-Perot cavity array to create a miniature spectrograph. It utilizes a number of electro-optic material plates with different thicknesses arranged in an array. Variation of voltage across electro-optical material varies the refractive index in the cavity and different thickness of the plates varies the cavity length. Hence, the variation of refractive index and cavity length together varies the bandwidth of the transmitted frequency.

CN 101858786 A discloses a device comprising a two-dimensional micro interferometer array on an upper surface of the substrate and an CCD at the lower surface of the substrate. Each micro interferometer is provided with a first step at a different height. The height changes are not linear and stepped surface may not be smooth.

U.S. Pat. No. 9,304,040 B2 discloses a method of using a plurality of etalon cavities on a substrate that provide a signal from a Fabry-Perot interferometer sampled as per Nyquist Shannon sampling criterion. The device is constructed as per the phase differential wavenumber criterion that sets an overall height range for the device to be able to achieve a certain wavenumber resolution in the spectrum. This signal is then used for reconstructing the spectrum via the standard Fourier transformation (FT) known from the FTIR spectroscopy. Following the Nyquist criterion, this approach requires tens of microns of device thickness whereby the cavity thickness differential must be maintained at 10 nm. Albeit its ease of spectral reconstruction, the manufacturing requirements are highly impractical for large-scale manufacturing.

The concept has been discussed in the chapter titled “Non Classical Fabry Perot Devices” in “Fabry Perot Interferometers” by G. Hernandez, Cambridge Studies in Modern Optics, Cambridge University Press, 1988.

U.S. Pat. No. 8,274,739 and WO 1995017690 A1 disclose a plasmonic Fabry-Perot filter including a first partial mirror and a second partial mirror separated by a gap. At least one of the mirror has an integrated plasmonic optical filter array. When light is incident on the array structures, at least one plasmon mode is resonant with the incident light to produce a transmission spectral window with desired spectral profile, bandwidth and beam shape. The height of the gap either increases along the width of the filter by tilting one of the mirror or remains constant along the width of the filter. If the gap height varies, then it can vary in discrete steps or continuously along the width of the filter. A transmission spectrum of a Fabry-Perot cavity structure usually shows multiple peaks with narrow passband width.

WO 2017147514 A1 discloses a method of patterning etalon array with varying thicknesses in polymer with pencil beam such as electron beam and coupling with an imaging detector such as CCD or CMOS. An array of 10 by 10 etalons with cavity thicknesses ranging from 1 to about 3 micrometers was demonstrated.

However, to-date, scientists only demonstrated the concept of reconstructive spectroscopy with etalon arrays of about 100 etalon cavities (e.g. a 10 by 10 field checkerboard). The etalon arrays were either manufactured by multi-layer lithography and subsequent wafer etching (see, for example, CN 101858786 A, and Xiao et al., Fabrication of CMOS-compatible optical filter arrays using gray-scale lithography, Journal of Micromechanics and Microengineering, Jan. 13, 2012, pp. 1-5, vol. 22, IOP Publishing, Ltd., UK) or by direct patterning techniques using pencil beams such as two-photon-absorption or electron beam lithography (see, for example, Huang, E. et al. Etalon Array Reconstructive Spectrometry. Sci. Rep. 7, 40693; doi: 10.1038/srep40693 (2017)). Moreover, currently achieved cavity thicknesses or depths (i.e., the distance between the two parallel semitransparent layers of an etalon) range from 1 to about 3 micrometers (see, for example, WO 2017147514 A1, and Huang, E., et al., Etalon Array Reconstructive Spectrometry, Sci. Rep. 7, 40693, doi: 10.1038/srep40693, (2017)), thereby placing a hard constraint on the achievable maximum resonant cavity thickness and thus limiting the resolution and/or the bandwidth of the spectrometer. Further, existing techniques are cumbersome, if not impractical, in producing large array etalons of required quality and quantities in a practical production time. As a result, no spectroscopic solution on the basis of etalon arrays for reconstructive spectroscopy is offered in the market to-date.

Given the current state of the art, there remains a need for optical arrays, optical devices and methods that address the abovementioned issues.

The information disclosed in this Background section is provided for an understanding of the general background of the invention and is not an acknowledgement or suggestion that this information forms part of the prior art already known to a person skilled in the art.

### SUMMARY

The present disclosure addresses, among others, a need in the art for optical arrays and optical devices that can be operated in narrow and wide spectral bands and at high spectral resolutions.

The present disclosure also addresses, among others, a need in the art for manufacturing optical arrays and optical devices that can be operated in narrow and wide spectral bands and at high spectral resolutions.

The present disclosure further addresses, among others, a need in the art for manufacturing filter arrays that include replicated etalon units and can be used as bandpass filters and optical devices having such filter arrays.

In some exemplary embodiments, the present disclosure provides a method for manufacturing one or more optical arrays. The method comprises: (A) providing a substrate comprising a first polymer layer sensitive to a radiation; (B) providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction; (C) positioning the substrate and the mask relative to each other at each relative position in a first plurality of relative positions along the first direction, wherein a distance between adjacent relative positions in the first plurality of relative positions is equal to or less than the first dimension of any second mask portion in the one or more second mask portions; (D) exposing, at each respective relative position in the first plurality of relative positions, the first polymer layer through the mask to a corresponding dose in a first plurality of doses of the radiation, thereby producing one or more first exposed polymer portions in the first polymer layer; (E) positioning the substrate and the mask relatively to each other at each relative position in a second plurality of relative positions along the second direction, wherein a distance between adjacent relative positions in the second plurality of relative positions is equal to or less than the second dimension of any second mask portion in the one or more second mask portions; and (F) exposing, at each respective relative position in the second plurality of relative positions, the first polymer layer through the mask to a corresponding dose in a second plurality of doses of the radiation, thereby producing one or more second exposed polymer portions in the first polymer layer, wherein each respective second exposed polymer portion in the one or more second exposed polymer portions overlaps at least partially with each corresponding first exposed polymer portion in the one or more first portions, thereby producing one or more overlapped exposed polymer portions, each overlapped exposed polymer portion creates an array of dosed segments, wherein each dosed segment in the array of dosed segments is exposed to a different dose of the radiation. In some exemplary embodiments, the method further comprises one or more of the following: (G) developing the first polymer layer of the substrate such that of each overlapped or final exposed polymer portion, each dosed segment in the array of dosed segments is developed to produce a first surface at a different depth in the first polymer layer, thereby creating one or more patterned structures in the first polymer layer of the substrate, each patterned structure comprising an array of first surfaces at different depths; (H) depositing a layer of a first reflective material on top of the one or more patterned structures; (I) overlaying a first protection layer on the layer of the first reflective material; (J) overlaying a second protection layer on the first protection layer; (K) dicing the substrate to produce one or more individual chips, each comprising a patterned structure in the one or more patterned structures; and (L) attaching a sensor array above or under each of the one or more patterned structures, wherein the sensor array is configured to detect light transmitted through the optical array, wherein the attaching (L) is performed prior to or subsequent to the dicing (K).

In some exemplary embodiments, the present disclosure provides a method for manufacturing one or more optical arrays. The method comprises: (A1) providing a substrate comprising a first polymer layer sensitive to a radiation; (B1) providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction; (C1) positioning the substrate and the mask relative to each other at each relative position in an array of relative positions, wherein a distance between two adjacent relative positions along the first direction is equal to n the first dimension of any second mask portion in the one or more second mask portions, and a distance between two adjacent relative positions along the second direction is equal to the second dimension of any second mask portion in the one or more second mask portions; and (D1) exposing, at each respective relative position in the array of relative positions, the first polymer layer through the mask to a corresponding dose in an array of doses of the radiation, thereby producing one or more final exposed polymer portions in the first polymer layer, each final exposed polymer portion comprising an array of dosed segments, wherein each dosed segment in the array of dosed segments is exposed to a different dose of the radiation. In some exemplary embodiments, the method further comprises one or more of the following: (G) developing the first polymer layer of the substrate such that of each overlapped or final exposed polymer portion, each dosed segment in the array of dosed segments is developed to produce a first surface at a different depth in the first polymer layer, thereby creating one or more patterned structures in the first polymer layer of the substrate, each patterned structure comprising an array of first surfaces at different depths; (H) depositing a layer of a first reflective material on top of the one or more patterned structures; (I) overlaying a first protection layer on the layer of the first reflective material; (J) overlaying a second protection layer on the first protection layer; (K) dicing the substrate to produce one or more individual chips, each comprising a patterned structure in the one or more patterned structures; and (L) attaching a sensor array above or under each of the one or more patterned structures, wherein the sensor array is configured to detect light transmitted through the optical array, wherein the attaching (L) is performed prior to or subsequent to the dicing (K).

In some exemplary embodiments, the present disclosure provides a method for mass replicating one or more optical arrays. The method comprises: (A) providing a master comprising one or more patterned structures, each patterned structure comprising an array of segments at different heights; (B) creating a replica comprising a first polymer layer, wherein the first polymer layer comprises one or more replicated structures, each replicated structure corresponding to a patterned structure in the one or more structures of the master, each replicated structure comprising an array of first surfaces at different depths corresponding to the array of segments at different heights; (C) depositing a layer of first reflective material on the first surfaces of each replicated structure in the one or more replicated structures, thereby producing a first reflective layer on the first surfaces of each replicated structure in the one or more replicated structures; (D) casting, subsequent to the depositing (C), a second polymer layer to the one or more replicated structures, wherein the second polymer layer comprises a planar polymer surface over each replicated structure in the one or more replicated structures; and (E) depositing, subsequent to the casting (D), a layer of second reflective material on the planar polymer surface over each replicated structure in the one or more replicated structures, thereby producing a second reflective layer on the planar polymer surface over each replicated structure in the one or more replicated structures, wherein corresponding to each replicated structure in the one or more replicated structures, an optical array is formed by the first reflective layer, the second reflective layer and the second polymer layer in-between. In some exemplary embodiments, the method further comprises one or more of the following: planarizing, subsequent to the casting (D) and prior to the depositing (E), the second polymer layer casted to the one or more replicated structures, thereby producing the planar polymer surface over each replicated structure in the one or more replicated structures; attaching a sensor array to the second reflective layer of each optical array, wherein the sensor array is configured to detect light transmitted through the optical array; manufacturing a polymer mold, wherein the polymer mold comprises one or more patterned mold structures in a third polymer layer, wherein each patterned mold structure comprises an array of mold surfaces at different depths; depositing a conductive film over the one or more patterned molded structures in the third polymer layer; and electroplating the conductive film over the one or more patterned mold structures in the third polymer layer with a layer of an electroplating material, thereby producing the master made of the electroplating material.

In some exemplary embodiments, the present disclosure provides a method for mass replicating one or more optical arrays. The method comprises: (A) providing a master comprising one or more patterned structures, each patterned structure comprising an array of segments at different heights; (B) creating a replica comprising a first polymer layer, wherein the first polymer layer comprises one or more replicated structures, each replicated structure corresponding to a patterned structure in the one or more structures of the master, each replicated structure comprising an array of first surfaces at different depths corresponding to the array of segments at different heights; (C) depositing a layer of first reflective material on the first surfaces of each replicated structure in the one or more replicated structures, thereby producing a first reflective layer on the first surfaces of each replicated structure in the one or more replicated structures; and (D) overlaying the first polymer layer on a substrate comprising a layer of second reflective material, wherein corresponding to each replicated structure in the one or more replicated structures, an optical array is formed by the first reflective layer, a second reflective layer formed by the layer of second reflective material, and the first polymer layer in-between. In some exemplary embodiments, the method further comprises one or more of the following processes: removing, prior to the overlaying (D), a residual layer from the first polymer layer under each replicated structure in the one or more replicated structures; attaching a sensor array to the second reflective layer of each optical array, wherein the sensor array is configured to detect light transmitted through the optical array; manufacturing a polymer mold, wherein the polymer mold comprises one or more patterned mold structures in a third polymer layer, wherein each patterned mold structure comprises an array of mold surfaces at different depths; depositing a conductive film over the one or more patterned molded structures in the third polymer layer; and electroplating the conductive film over the one or more patterned mold structures in the third polymer layer with a layer of an electroplating material, thereby producing the master made of the electroplating material.

In some exemplary embodiments, the present disclosure provides a method for manufacturing one or more filter arrays each with replicated units. The method comprises: (A) providing a substrate comprising a first polymer layer sensitive to a radiation; (B) providing a single mask comprising a first mask portion and one or more second mask portion arrays, wherein the first mask portion is configured to block the radiation, and each second mask portion array in the one or more second mask portion arrays comprises an array of second mask portions configured to allow the radiation to pass through, wherein each second mask portion in the array of second mask portions has a first dimension in a first direction and a second dimension in a second direction, wherein the second direction is different from the first direction; (C) positioning the substrate and the mask relative to each other at each relative position in an array of relative positions, wherein a distance between two adjacent relative positions along the first direction is equal to in the first dimension of any second mask portion in the array of second mask portions, and a distance between two adjacent relative positions along the second direction is equal to the second dimension of any second mask portion in the array of second mask portions; and (D) exposing, at each respective relative position in the array of relative positions, the first polymer layer through the mask to a corresponding dose in an array of doses of the radiation, thereby producing one or more exposed polymer portions in the first polymer layer, wherein each exposed polymer portion comprises an array of dosed units and each dosed unit comprises an array of dosed segments, wherein of each dosed unit, at least two dosed segments are exposed to different doses of the radiation. In some exemplary embodiments, the method further comprises one or more of the following: (E) developing the first polymer layer of the substrate such that each exposed polymer portion produces a patterned structure, thereby creating one or more patterned structures in the first polymer layer of the substrate, wherein each patterned structure comprises an array of structure units, each structure unit comprising an array of first surfaces, wherein of each structure unit of each patterned structure, at least two first surfaces are at different depths; (F) depositing a layer of a first reflective material on top of the one or more patterned structures; (G) overlaying a first protection layer on the layer of the first reflective material; (H) overlaying a second protection layer on the first protection layer; (I) dicing the substrate to produce one or more individual chips, each comprising a patterned structure in the one or more patterned structures; and (J) attaching a sensor array to the layer of the second reflective material above each of the one or more patterned structures or to the substrate under each of the one or more patterned structures, wherein the sensor array is configured to detect light transmitted through the optical array, wherein the attaching is performed prior to or subsequent to the dicing (I).

In some exemplary embodiments, the present disclosure provides a method for mass replicating one or more filter arrays each with replicated units. The method comprises: (A) providing a master comprising one or more patterned structures, each patterned structure comprising an array of structure unit, each structure unit comprising an array of segments, wherein of each structure unit, at least two segments in the array of segments are at different heights; (B) creating a replica comprising a first polymer layer, wherein the first polymer layer comprises one or more replicated structures, each replicated structure corresponding to a patterned structure in the one or more structures of the master, each replicated structure comprising an array of replicated structure units, each replicated structure unit comprising an array of first surfaces, wherein of each replicated structure unit, at least two first surfaces in the array of first surfaces are at different depths; (C) depositing a layer of first reflective material on the first surfaces of each replicated structure in the one or more replicated structures, thereby producing a first reflective layer on the first surfaces of each replicated structure unit of each replicated structure in the one or more replicated structures; (D) casting, subsequent to the depositing (C), a second polymer layer to the one or more replicated structures, wherein the second polymer layer comprises a planar polymer surface over each replicated structure in the one or more replicated structures; and (E) depositing, subsequent to the casting (D), a layer of second reflective material on the planar polymer surface over each replicated structure in the one or more replicated structures, thereby producing a second reflective layer on the planar polymer surface over each replicated structure in the one or more replicated structures, wherein corresponding to each replicated structure in the one or more replicated structures, an optical array is formed by the first reflective layer, the second reflective layer and the second polymer layer in-between. In some exemplary embodiments, the method further comprises one or more of the following: planarizing, subsequent to the casting (D) and prior to the depositing (E), the second polymer layer casted to the one or more replicated structures, thereby producing the planar polymer surface over each replicated structure in the one or more replicated structures; attaching a sensor array to the second reflective layer of each optical array, wherein the sensor array is configured to detect light transmitted through the optical array; manufacturing a polymer mold, wherein the polymer mold comprises one or more patterned mold structures in a third polymer layer, wherein each patterned mold structure comprises an array of mold structure units, each mold structure unit comprising an array of mold surfaces at different depths; depositing a conductive film over the one or more patterned molded structures in the third polymer layer; and electroplating the conductive film over the one or more patterned mold structures in the third polymer layer with a layer of an electroplating material, thereby producing the master made of the electroplating material.

In some exemplary embodiments, the present disclosure provides a method for mass replicating one or more filter arrays each with replicated units. The method comprises: (A) providing a master comprising one or more patterned structures, each patterned structure comprising an array of structure unit, each structure unit comprising an array of segments, wherein of each structure unit, at least two segments in the array of segments are at different heights; (B) creating a replica comprising a first polymer layer, wherein the first polymer layer comprises one or more replicated structures, each replicated structure corresponding to a patterned structure in the one or more structures of the master, each replicated structure comprising an array of replicated structure units, each replicated structure unit comprising an array of first surfaces, wherein of each replicated structure unit, at least two first surfaces in the array of first surfaces are at different depths; (C) depositing a layer of first reflective material on the first surfaces of each replicated structure in the one or more replicated structures, thereby producing a first reflective layer on the first surfaces of each replicated structure unit of each replicated structure in the one or more replicated structures; and (D) overlaying the first polymer layer on a substrate comprising a layer of second reflective material, wherein corresponding to each replicated structure in the one or more replicated structures, an optical array is formed by the first reflective layer, a second reflective layer formed by the layer of second reflective material, and the first polymer layer in-between. In some exemplary embodiments, the method further comprises one or more of the following: removing, prior to the overlaying (D), a residual layer from the first polymer layer under each replicated structure in the one or more replicated structures; attaching a sensor array to the substrate under each optical array, wherein the sensor array is configured to detect light transmitted through the optical array; manufacturing a polymer mold a polymer mold, wherein the polymer mold comprises one or more patterned mold structures in a third polymer layer, wherein each patterned mold structure comprises an array of mold structure unit, each mold structure unit comprising an array of mold surfaces at different depths; depositing a conductive film over the one or more patterned molded structures in the third polymer layer; and electroplating the conductive film over the one or more patterned mold structures in the third polymer layer with a layer of an electroplating material, thereby producing the master made of the electroplating material.

In some exemplary embodiments, the present disclosure provides an optical array. The optical array can be made by the methods disclosed herein or the like. In some exemplary embodiments, the optical array comprises at least 1000 etalons, each having a different depth and configured to generate a different transmission pattern when impinged by a light, such that the optical array enables recovery of both narrow and wide spectral bands at high spectral resolutions. In some exemplary embodiments, the optical array comprises an array of etalons, each etalon having a different depth and configured to generate a different transmission pattern when impinged by a light, wherein the depths of at least two etalons in the array differ from each other by two to three orders of magnitude, such that the optical array enables recovery of both narrow and wide spectral bands at high spectral resolutions.

The optical arrays, optical devices and methods of the present invention have other features and advantages that will be apparent from or are set forth in more detail in the accompanying drawings, which are incorporated herein, and the following Detailed Description, which together serve to explain certain principles of exemplary embodiments of the present invention.

### BRIEF DESCRIPTION OF THE DRAWINGS

FIG. 1A illustrates schematically a top view of an exemplary large etalon array in accordance with some exemplary embodiments of the present disclosure.

FIG. 1B illustrates schematically a cross section view taken along line 1B-1B of FIG. 1A in accordance with some exemplary embodiments of the present disclosure.

FIG. 1C illustrates schematically a cross section view taken along line 1C-1C of FIG. 1A in accordance with some exemplary embodiments of the present disclosure.

FIG. 2 is a plot illustrating the effect of the number of etalons and other characteristics of an etalon array on the recovery of input spectra in accordance with some exemplary embodiments of the present disclosure.

FIG. 3 is a plot illustrating the effect of the cavity depths and other characteristics of an etalon array on the recovery of input spectra in accordance with some exemplary embodiments of the present disclosure.

FIGS. 4A and 4B are exemplary flow charts describing an exemplary method for manufacturing large etalon arrays in accordance with some exemplary embodiments of the present disclosure.

FIG. 5A illustrates schematically an exemplary setup for fabricating large etalon arrays in accordance with some exemplary embodiments of the present disclosure.

FIG. 5B illustrates schematically exposure of a polymer layer to radiation at relative positions along a first direction in accordance with some exemplary embodiments of the present disclosure.

FIG. 5C illustrates schematically exposure of a polymer layer to radiation at relative positions along a second direction in accordance with some exemplary embodiments of the present disclosure.

FIG. 5D illustrates schematically a cross-sectional view taken along line 5D-5D of FIG. 5C in accordance with some exemplary embodiments of the present disclosure.

FIG. 5E illustrates schematically a top view of a portion of the mask of FIG. 5A in accordance with some exemplary embodiments of the present disclosure.

FIG. 5F illustrates schematically a top view of a portion of the polymer layer of FIG. 5A after exposure of irradiation along the first direction in accordance with some exemplary embodiments of the present disclosure.

FIG. 5G illustrates schematically a top view of a portion of the polymer layer of FIG. 5A after exposure of irradiation along the first and second directions in accordance with some exemplary embodiments of the present disclosure.

FIG. 5H illustrates schematically a cross-sectional view of an exemplary patterned structure in accordance with some exemplary embodiments of the present disclosure.

FIG. 5I illustrates schematically a cross-sectional view of an exemplary optical array in accordance with some exemplary embodiments of the present disclosure.

FIG. 6 is an exemplary flow chart describing another exemplary method for manufacturing large etalon arrays in accordance with some exemplary embodiments of the present disclosure.

FIG. 7A illustrates schematically another exemplary setup for fabricating large etalon arrays in accordance with some exemplary embodiments of the present disclosure.

FIG. 7B illustrates schematically exemplary positioning of the substrate and the mask relative to each other at relative positions in accordance with some exemplary embodiments of the present disclosure.

FIGS. 8A and 8B are exemplary flow charts describing an exemplary method for mass replicating large etalon arrays in accordance with some exemplary embodiments of the present disclosure.

FIGS. 9A-9J illustrate schematically some processes of the method in FIGS. 8A and 8B in accordance with some exemplary embodiments of the present disclosure.

FIG. 10 is an exemplary flow chart describing another exemplary method for mass replicating large etalon arrays in accordance with some exemplary embodiments of the present disclosure.

FIGS. 11A-11C illustrate schematically some processes of the method in FIG. 10 in accordance with some exemplary embodiments of the present disclosure.

FIG. 12 illustrates schematically a top view of an exemplary filter array including replicated etalon units in accordance with some exemplary embodiments of the present disclosure.

FIG. 13 is an exemplary flow chart describing an exemplary method for fabricating exemplary filter arrays in accordance with some exemplary embodiments of the present disclosure.

FIG. 14A illustrates schematically a top view of an exemplary mask for fabricating exemplary filter arrays in accordance with some exemplary embodiments of the present disclosure.

FIG. 14B illustrates schematically a top view of exemplary exposed polymer portions in accordance with some exemplary embodiments of the present disclosure.

FIG. 14C illustrates schematically a top view of an exemplary patterned structure in accordance with some exemplary embodiments of the present disclosure.

FIG. 14D illustrates schematically a bottom-perspective view of an exemplary structure unit in accordance with some exemplary embodiments of the present disclosure.

FIG. 14E illustrates schematically a cross-sectional view taken along line 14E-14E of FIG. 14C in accordance with some exemplary embodiments of the present disclosure.

FIG. 14F illustrates schematically a cross-sectional view of an exemplary optical array in accordance with some exemplary embodiments of the present disclosure.

FIG. 15 is an exemplary flow chart describing an exemplary method for mass replicating exemplary filter arrays in accordance with some exemplary embodiments of the present disclosure.

FIG. 16 is an exemplary flow chart describing another exemplary method for mass replicating exemplary filter arrays in accordance with some exemplary embodiments of the present disclosure.

In accordance with common practice, the various features illustrated in the drawings may not be drawn to scale. The dimensions of various features may be arbitrarily expanded or reduced for clarity. In addition, some of the drawings may not depict all of the components of a given system, method or device. The components illustrated in the figures described above are combinable in any useful number and combination. Finally, like reference numerals may be used to denote like features throughout the specification and figures.

### DETAILED DESCRIPTION

Reference will now be made in detail to implementations of the exemplary embodiments of the present invention as illustrated in the accompanying drawings. The same reference indicators will be used throughout the drawings and the following detailed description to refer to the same or like parts. Those of ordinary skill in the art will understand that the following detailed description is illustrative only and is not intended to be in any way limiting. Other embodiments of the present invention will readily suggest themselves to such skilled persons having benefit of this disclosure.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Many modifications and variations of the embodiments set forth in this disclosure can be made without departing from their spirit and scope, as will be apparent to those skilled in the art. The specific embodiments described herein are offered by way of example only, and the disclosure is to be limited only by the terms of the appended claims, along with the full scope of equivalents to which such claims are entitled.

In various exemplary embodiments, the present disclosure provides large etalon arrays, devices having large etalon arrays, and methods of manufacturing such large etalon arrays and devices. The present disclosure also provides filter arrays with replicated etalon units, devices having filter arrays, and methods of manufacturing such filter arrays and devices having filter arrays.

As used herein, the term “etalon” referred to a resonant cavity formed by two parallel or substantially parallel reflective layers a distance apart. In some exemplary embodiments, the space between the two reflective layers is filled with a material transparent to the incoming light. When illuminated with a beam of electromagnetic radiation, only wavelengths satisfying the condition (e.g., λₙ=L/2n, n=1, 2, 3, . . . ) form standing waves reflecting back and forth within the cavity, add constructively, transmit through the cavity and exit with maximum intensity. Other wavelengths are reflected back and rejected from transmission or produce lesser transmission. Thus, by adjusting the distance of the cavity, the transmission characteristic of each individual cavity can be tuned.

As used herein, the distance between the two reflective layers is interchangeable with “cavity thickness”, “cavity depth”, “etalon thickness”, or “etalon depth”.

As used herein, the term “array” refers to a number of objects (e.g., etalons) arranged in one-dimensional, two-dimensional, or other patterns, or in some cases, arbitrarily arranged.

As used here, the term “large etalon array” refers to a relatively large number of etalons arranged in one-dimensional, two-dimensional, or other patterns, or in some cases, arbitrarily arranged. For instance, in some exemplary embodiments, a large etalon array includes hundreds, thousands or more than thousands of resonant cavities. Of the large etalon array, the distance of each individual cavity is unique and different from its neighboring cavities. In some exemplary embodiments, the term “large etalon array” or “large etalon arrays” refers to an etalon array or etalon arrays in terms of the number of resonant cavities per etalon array, the number of etalon arrays per wafer, and/or the actual size of an etalon array.

As used herein, the term “etalon unit” refers to a relatively small number of etalons arranged in one-dimensional, two-dimensional, or other patterns, or in some cases, arbitrarily arranged. For instance, in some exemplary embodiments, an etalon unit includes less than 50 or less than 100 etalons. Different etalons in the etalon unit can have the same depth or different depths. In some exemplary embodiments, each etalon of the etalon unit is configured such that the transmission pattern through each etalon contains a single peak, e.g., each etalon functions as an optical bandpass filter.

As used herein, the term “filter array with replicated etalon units” refers to a filter array having a number of replicated etalon units arranged in one-dimensional, two-dimensional, or other patterns.

I. Exemplary Large Etalon Arrays

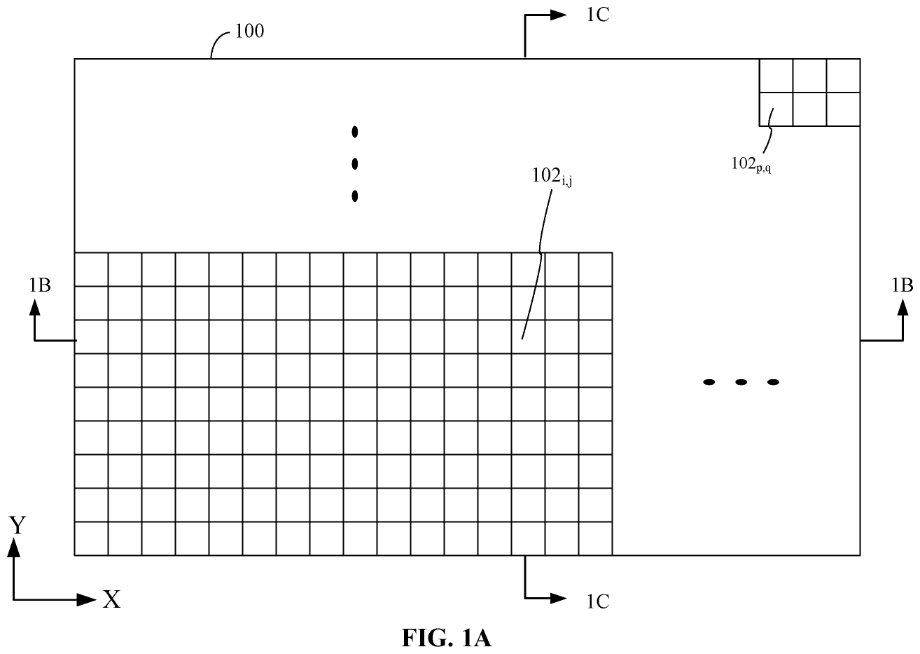

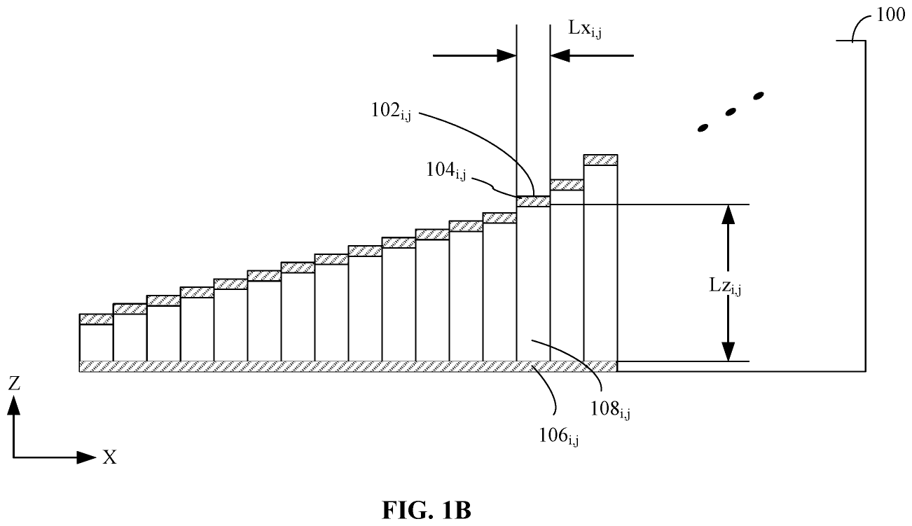

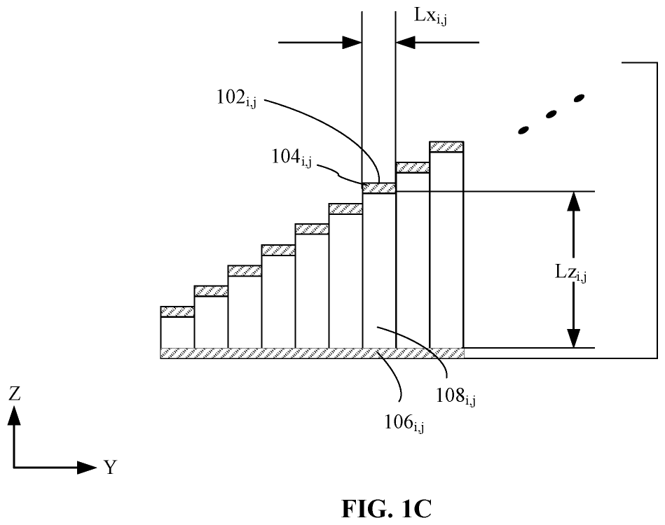

FIGS. 1A-1C illustrate exemplary large etalon array 100 of the present disclosure in accordance with some embodiments. Etalon array 100 includes a large number of etalons 102, for instance at least 1000 etalons. In some exemplary embodiments, etalon array 100 includes between 1000 and 2000 etalons, between 2000 and 5000 etalons, or between 5000 and 10000 etalons. These etalons are arranged in one-dimensional, two-dimensional, or other patterns, or arbitrarily. In some exemplary embodiments, these etalons are arranged in an M×N array, where M is any integer between 1 and 5000, and N is any integer between 1 and 5000. In some exemplary embodiments, M is any integer between 3 and 10, between 10 and 20, between 20 and 50, between 50 and 100, between 100 and 200, between 200 and 500, or between 500 and 1000; and N is any integer between 3 and 10, between 10 and 20, between 20 and 50, between 50 and 100, between 100 and 200, between 200 and 500, or between 500 and 1000.

Each etalon 102 includes two parallel reflective layers a distance apart. For instance, etalon 102_{i,j} includes first reflective layer 104_{i,j} and second reflective layer 106_{i,j} disposed apart with a distance of Lz_{i,j} in between. The first and second reflective layers can be made of the same material or different materials, and can have the same thickness or different thicknesses. For instance, in an exemplary embodiment, the first and/or second reflective layer is made from the same material such as aluminum or the like, and has a thickness between 5 and 10 nm, between 10 and 15 nm, between 15 and 20 nm, between 20 and 25 nm, or between 25 and 30 nm.

The distance Lz_{i,j} is unique for etalon 102_{i,j} and is different from the distances of all other etalons in etalon array 100. For instance, Lz_{i,j} is different from Lz_{p,q} if p≠i and/or q≠j. As such, when impinged by a light, each etalon 102 will generate a different transmission pattern.

Etalon array 100 has a wide range of etalon depths, for instance, from less than 100 nanometers to greater than 100 micrometers (>3 orders of magnitude). In some exemplary embodiments, the depths of etalon array 100 range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm. In some exemplary embodiments, the distances or depths of at least two etalons in etalon array 100 differ from each other by at least two orders of magnitude. In some exemplary embodiments, the distances or depths of at least two etalons in etalon array 100 differ from each other by at least three orders of magnitude. For instance, in an embodiment, depth Lz_{p,q} of etalon 102_{p,q} is two or three orders of magnitude larger than depth Lz_{i,j} of etalon 102_{i,j}.

The increments of the depths of different etalons across etalon array 100 can be uniform, e.g., the increments of the depths are the same among the etalons along the first and/or second directions of etalon array 100. The increments of the depths of different etalons across etalon array 100 can also be non-uniform, e.g., the increments of the depths are different for at least two etalons among the etalons along the first and/or second directions of etalon array 100. As a non-limiting example, FIG. 1B illustrates a non-uniform increment of the depths along the first direction, and FIG. 1C illustrates a uniform increment of the depths along the second direction etalon array 100. In some exemplary embodiments, the increment of the depths of etalon array 100 is in the range of tens of nanometers.

Etalons of etalon array 100 can have any suitable shapes and sizes in the plane perpendicular to the depths (e.g., in the x-y plane), which are characterized by first and second characteristic dimensions. For instance, etalon 102_{i,j} is characterized by first characteristic dimension Lx_{i,j} and second characteristic dimension Ly_{i,j}. In some exemplary embodiments where etalon 102_{i,j} is a rectangle or a square, Lx_{i,j} represents the length of etalon 102_{i,j} along the first direction (e.g., x direction) and Ly_{i,j} represents the length of etalon 102_{i,j} along the second direction (e.g., y direction). In some exemplary embodiments where etalon 102_{i,j} has a shape other than a rectangle or a square such as a circle or an oblong, Lx_{i,j} and Ly_{i,j} represent the equivalent lengths (e.g., diameter or the like) of etalon 102_{i,j} along the first and second directions, respectively. Lx_{i,j} and Ly_{i,j} can be the same as (e.g., square) or different (e.g., rectangle) from each other. Lx_{i,j} and/or Ly_{i,j} can be the same as Lx_{p,q} and/or Ly_{p,q} (e.g., etalon 102_{i,j} and etalon 102_{p,q} have the same first and/or second characteristic length), or different from Lx_{p,q} and/or Ly_{p,q} (e.g., etalon 102_{i,j} and etalon 102_{p,q} have different first and/or second characteristic lengths). In some exemplary embodiments, Lx_{i,j} is 0.1 μm and 1 μm, between 1 μm and 10 μm, between 10 μm and 20 μm, or between 20 μm and 30 μm, where i is any integer from 1 to M and j is any integer from 1 to N. In some exemplary embodiments, Ly_{i,j} is 0.1 μm and 1 μm, between 1 μm and 10 μm, between 10 μm and 20 μm, or between 20 μm and 30 μm, where i is any integer from 1 to M and j is any integer from 1 to N. As a non-limiting example, FIGS. 1A-1C illustrates each etalon 102 of etalon array 100 has the same square shape and size.

In some exemplary embodiments, the space between the first and second reflective layers (e.g., space 108_{i,j} between first reflective layer 104_{i,j} and second reflective layer 106_{i,j} of etalon 102_{i,j}) is filled with a material that is transparent to the light to be impinged on the etalon array. The material can be selected based on the applications of etalon array 100. In some exemplary embodiments, the material is transparent or substantially transparent to the visible light or other spectral ranges including far-infrared, mid-infrared and near-infrared. In some exemplary embodiments, the material is transparent or substantially transparent to the spectrum of the light ranging from 360 nm to 1500 nm, from 300 nm to 2000 nm, or 200 to 2200 nm. Examples of the material include, but are not limited to, polymers such as a Poly(methyl methacrylate) (PMMA) or the like.

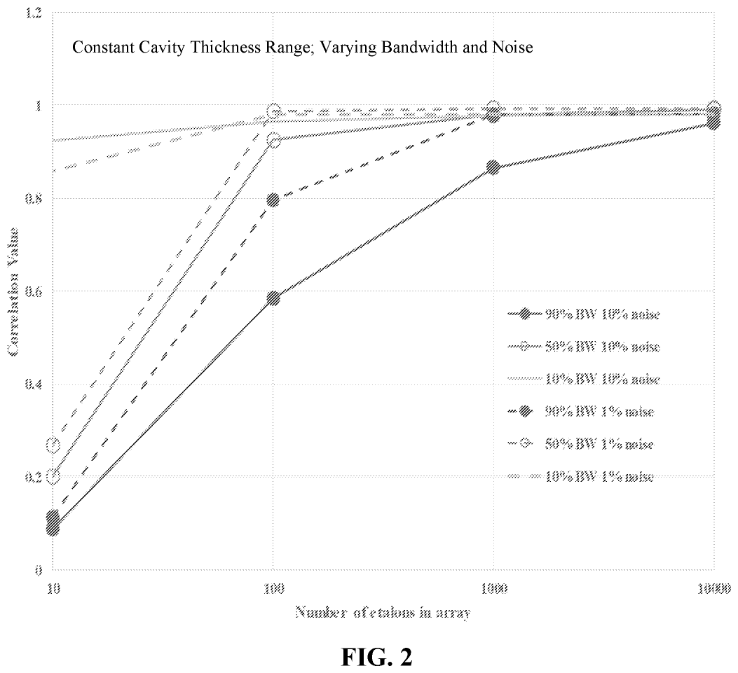

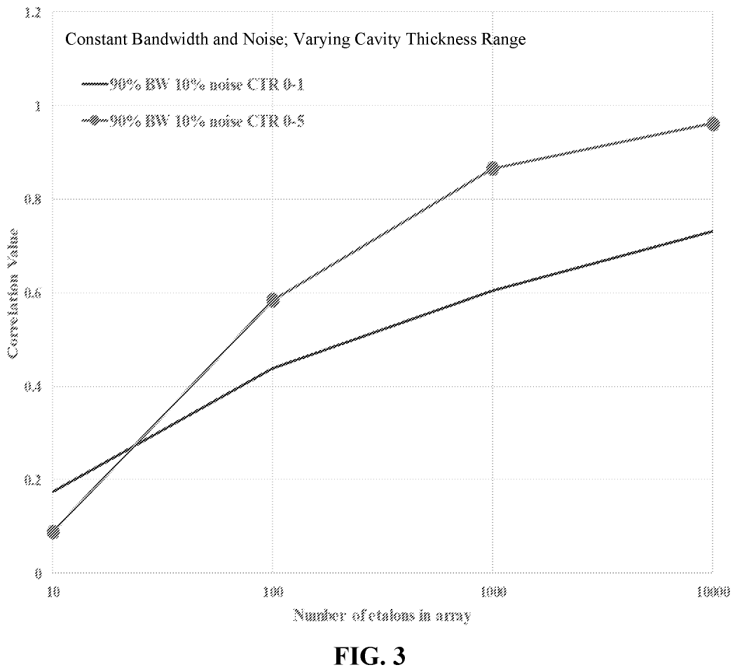

Etalon array 100 provides a number of advantages that are not conceivable with the existing conventional etalon arrays. For instance, it enables the recovery of both narrow and wide spectral bands at high spectral resolutions. This is illustrated in FIGS. 2 and 3, where the impacts of some parameters on the recovery of an input spectrum are investigated and exemplary simulation results are presented. Both figures plot the Correlation Value between recovered spectra and the ground truth in the presence of additive random white noise of 1% and 10% of the signal magnitude. Examples of the parameters investigated include the number of etalons in the etalon array, the Wavelength Bandwidth (BW) in % total bandwidth illuminating the etalon array, and the etalon Cavity Thickness Range (CTR) for two thickness ranges (e.g., 0-1 micrometer and 0-5 micrometer).

In FIG. 2, the number of etalons in the etalon array ranges from 10 to 10,000 etalons, the wavelength bandwidth illuminating the etalon array is 10%, 50% or 90% of a spectral bandwidth of 400 to 800 nm, and the magnitude of noise is 1% or 10%. The spectra are recovered at a wavelength stepping (e.g., 1 nm) and correlated against the ground truth of the input spectrum. A correlation value representing the accuracy of the recovery is obtained as a function of the number of etalons in the etalon array, the wavelength bandwidth illuminating the etalon array, and the magnitude of noise. For instance, in FIG. 2, the dashed line represents the correlation value versus the number of etalons in the etalon array under 10% BW and 1% noise. The solid line represents the correlation value versus the number of etalons in the etalon array under 10% BW and 10% noise. The dashed line with open dots represents the correlation value versus the number of etalons in the etalon array under 50% BW and 1% noise. The solid line with open dots represents the correlation value versus the number of etalons in the etalon array under 50% BW and 10% noise. The dashed line with solid dots represents the correlation value versus the number of etalons in the etalon array under 90% BW and 1% noise. The solid line with solid dots represents the correlation value versus the number of etalons in the etalon array under 90% BW and 10% noise.

In FIG. 2, a correlation value of 1 means accurate recovery, whereas values smaller than 1 denote erroneous spectral recovery. As can be seen, while depending on the BW and the magnitude of noise, the accuracy of the recovery improves and the correlation value asymptotically reaches 1 for larger etalon numbers in all cases. For instance, under 90% BW and 10% noise, an etalon array with 1000 etalons achieves a correlation value of 86%, whereas an etalon array with 100 etalons only achieves a correlation value of 58% under the same BW and magnitude of noise. With detectors (e.g., common low-cost CMOS) featuring noise magnitudes in the order of 1-10%, only etalon arrays having etalons in the range of 1000 or above allow satisfactory recoveries of both narrow and broad band spectra.

In FIG. 3, the solid line represents the correlation value versus the number of etalons in the etalon array under 90% BW, 10% noise, and CTR of 0 to 1 μm. The solid line with solid dots represents the correlation value versus the number of etalons in the etalon array under 90% BW, 10% noise and CTR of 0 to 5 μm. As can be seen, the range of the etalon cavity thicknesses or the maximum etalon cavity thickness plays an important role in successful spectral recovery from etalon arrays. For instance, under 90% BW, 10% noise and CTR of 0 to 5 μm, an etalon array with 1000 etalons achieves a correlation value higher than 80%, whereas under 90% BW, 10% noise and CTR of 0 to 1 μm, an etalon array with 1000 etalons achieves a correlation value of about 60%.

With the etalon arrays of the present disclosure, spectrometers are operable in both narrow and wide spectral bands and at high spectral resolutions.

II. Exemplary Methods for Fabricating Large Etalon Arrays and Optical Devices Having Large Etalon Arrays

II-1. Exemplary Method 400

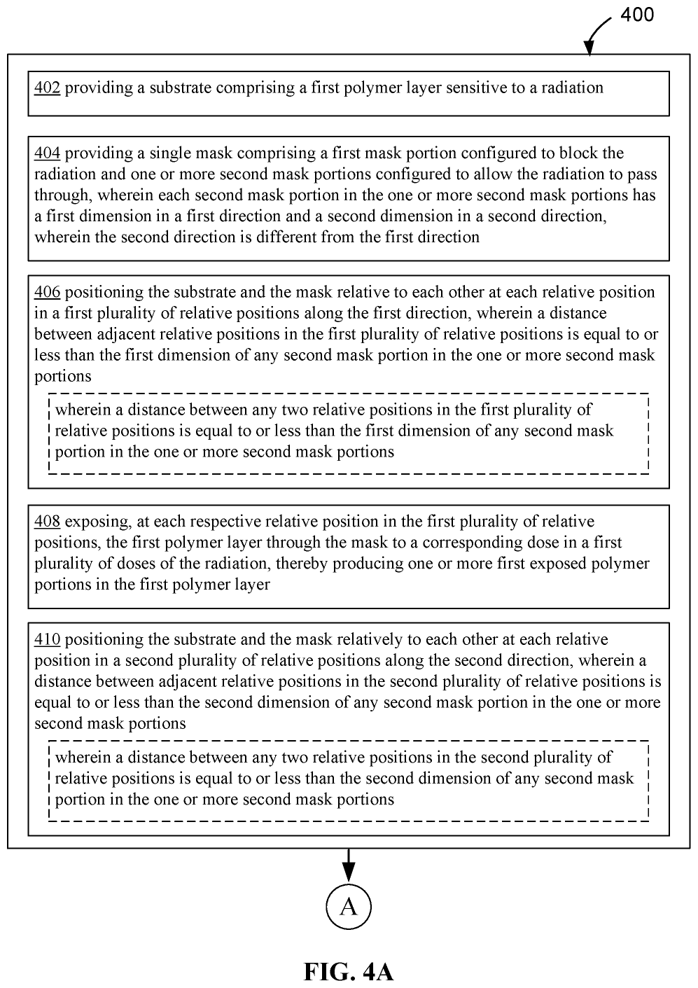

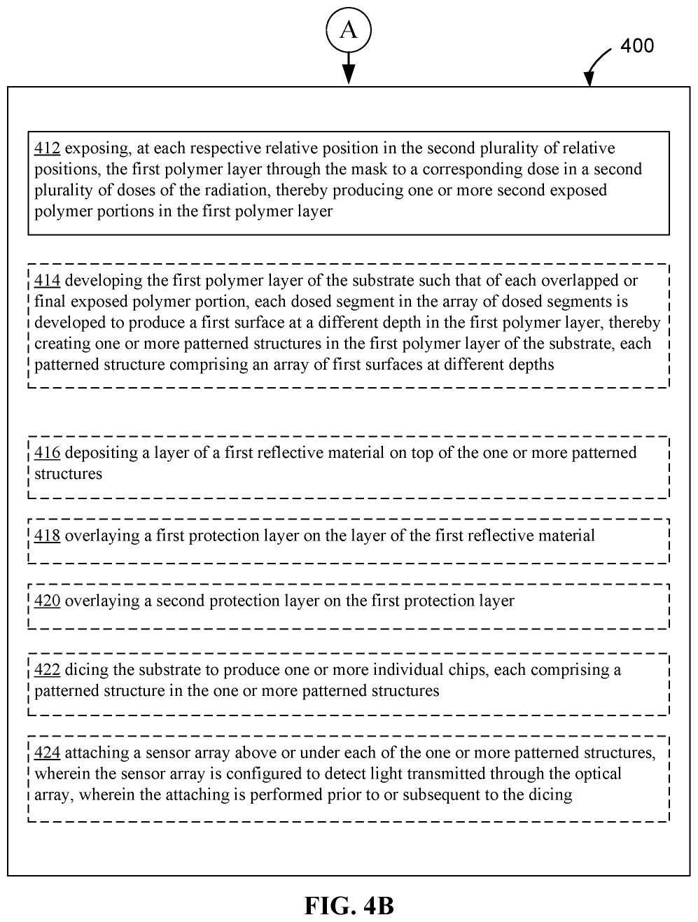

FIGS. 4A and 4B illustrate flow charts describing exemplary method 400 for manufacturing large etalon arrays and optical devices having larger etalon arrays in accordance with some exemplary embodiments of the present disclosure. Method 400 can be performed by a lithographic apparatus such that those disclosed in U.S. Pat. No. 9,400,432, which is incorporated herein by reference in its entirety for all purposes.

Method 400 in general includes irradiating a polymer layer through a single mask. The polymer layer and/or the mask are moved relative to each other along two different directions. At each relative position, the polymer layer is exposed, through the mask, to a corresponding dose of a radiation. The dose is controlled by controlling the duration of the exposure, intensity of the radiation, and/or the number of overlapping exposures. The exposed polymer layer is then developed (e.g., using a wet chemistry), thereby creating a three-dimensional topography in the polymer layer. In some exemplary embodiments, two reflective layers are deposited and a wafer is subsequently diced to produce individual chips each including a large etalon array.

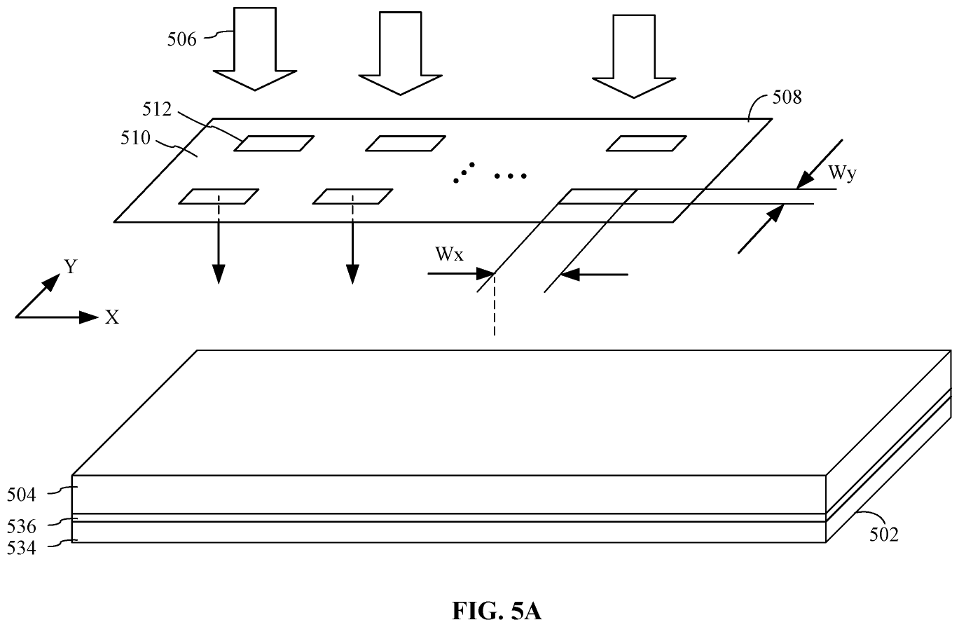

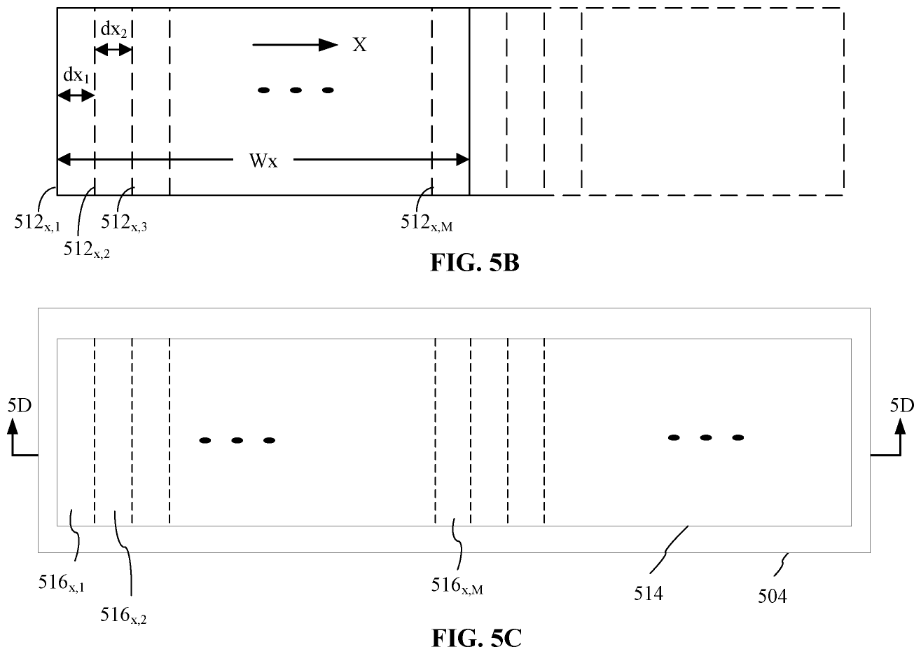

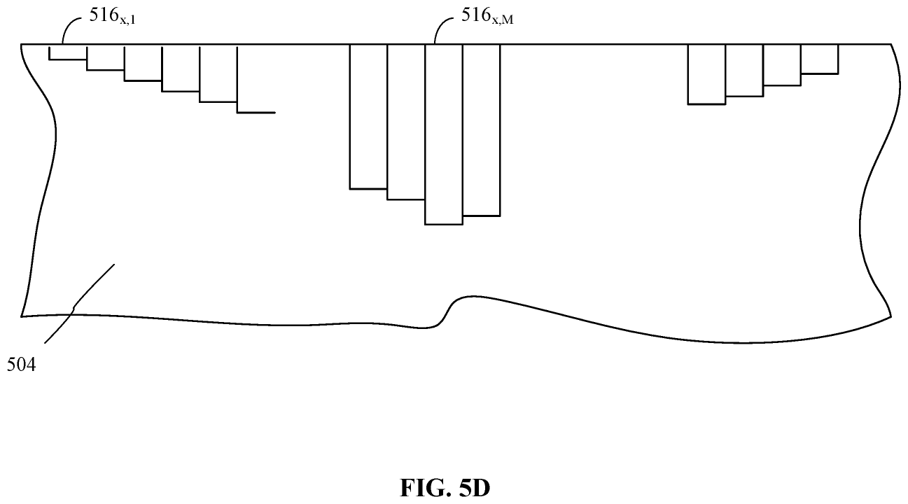

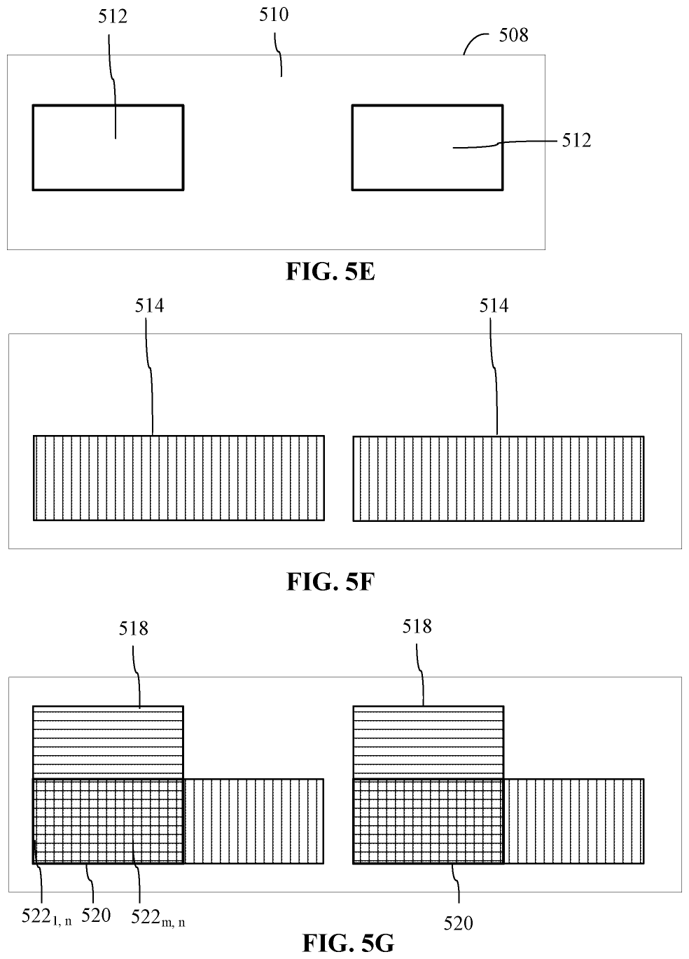

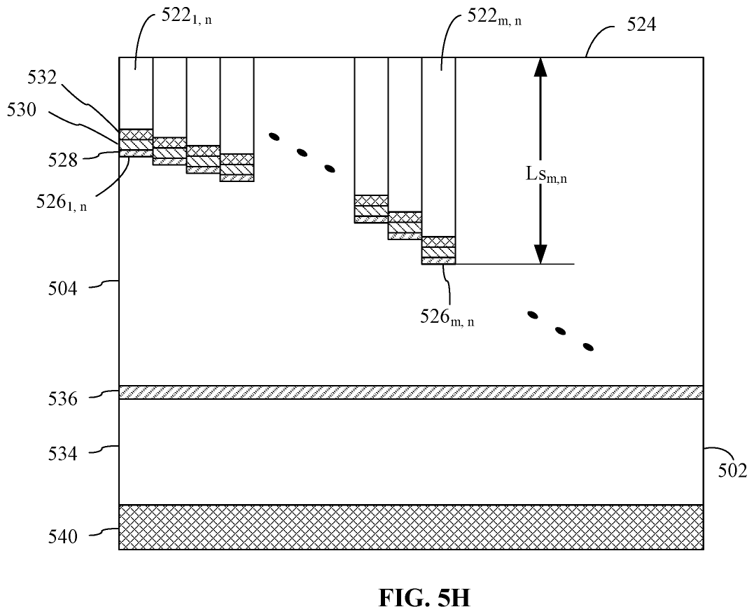

Block 402. With reference to block 402 of FIG. 4A, method 400 includes providing a substrate comprising a first polymer layer sensitive to a radiation. The substrate can be of any suitable shapes and sizes, and can have one layer or multiple layers. For instance, in some exemplary embodiments, the substrate is a wafer with a characteristic dimension (e.g., diameter) between 150 mm and 200 mm, between 200 mm and 300 mm, or between 300 mm and 500 mm. By way of example, FIG. 5A illustrates substrate 502 having first polymer layer 504 on top.

In some exemplary embodiments, first polymer layer 504 is a photosensitive resist that is sensitive to radiation 506. Examples of radiation 506 include but are not limited to an X-ray beam or a UV beam. Examples of first polymer layer 504 include but are not limited to a Poly(methyl methacrylate) (PMMA) or the like. In some exemplary embodiments, the first polymer layer has a thickness between 2 and 5 μm, between 5 and 10 μm, between 10 and 15 μm, between 15 and 20 μm, between 20 and 30 μm, between 30 and 50 μm, or between 50 and 100 μm. Radiation 506 and first polymer layer 504 are typically arranged such that radiation 506 is substantially perpendicular to the surface of first polymer layer 504. However, in special cases, an inclination angle between radiation 506 and first polymer layer 504 is also possible and useful

Block 404. With reference to block 404 of FIG. 4A, method 400 includes providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction.

The one or more second mask portions can have any suitable shapes including but not limited to rectangle, square, polygon, circle or the like. The one or more second mask portions can have any suitable sizes including but not limited to 0.001×0.001 and 0.1×0.1 mm², between 1×1 and 1.5×1.5 mm², between 1.5×1.5 and 2×2 mm², between 2×2 and 2.5×2.5 mm², or between 2.5×2.5 and 3×3 mm². In some exemplary embodiments, the shape and size of the desired large etalon arrays to be fabricated are taken into consideration in determining the configuration of the second mask portions. In an exemplary embodiment, a second mask portion has the same configuration as the desired large etalon array. In another exemplary embodiment, a second mask portion has a different configuration, for instance, smaller or larger than the size of the desired large etalon array.

For cases with multiple second portions, second mask portions can have the same configuration (e.g., same shape and same size), or different configurations (e.g., different shapes, or different sizes, or both). In addition, the second mask portions can be spatially distributed across the mask in any suitable ways, including but not limited to one-dimensional, two dimensional, circular, diamond, or other patterns. In some exemplary embodiments, the second portions are arbitrarily distributed across the mask.

As a non-limiting example, FIG. 5A illustrates mask 508 having first mask portion 510 and multiple second mask portions 512 arranged in a two-dimensional array across mask 508. First mask portion 510 is configured to block radiation 506, for instance by absorption or reflection or both. Second mask portions 512 are configured to allow the radiation to pass through and then impinge on the first polymer layer. In an exemplary embodiment, second mask portions 512 are holes on mask 508. Second mask portion 512 has a first dimension in a first direction, e.g., first dimension Wx in the x-direction, and a second dimension in a second direction, e.g., second dimension Wy in the y-direction. The second direction is different from the first direction. In some exemplary embodiments, the first and second directions are perpendicular to each other.

It should be noted that the first and second dimensions are characteristic dimensions of a second mask portion. In cases where the second mask portion is a rectangle or a square, the first dimension is the length of the second mask portion along the first direction and the second dimension is the length of the second mask portion along the second direction. In cases where the second mask portion has a shape other than a rectangle or a square, the first and second dimensions are the equivalent lengths of the second mask portions along the first and second directions, respectively. It should also be noted that in cases where two second mask portions have different shapes or sizes, the first dimensions and/or the second dimensions for these two second mask portions can be different.

In some exemplary embodiments, mask 508 includes between 10 and 50, between 50 and 100, between 100 and 150, between 150 and 200, between 200 and 300, between 300 and 400, or between 400 and 500 second mask portions that are spatially separated from each another. This will result in between 10 and 50, between 50 and 100, between 100 and 150, between 150 and 200, between 200 and 300, between 300 and 400, or between 400 and 500 large etalon arrays per substrate (e.g., per wafer).

In some exemplary embodiments, at least two second mask portions have the same configuration (e.g., same shape, same size and same orientation). In some exemplary embodiments, at least two second mask portions have different configurations (e.g., different in shape, size, orientation, or any combination). In an exemplary embodiment, each and every second mask portion has the same configuration.

Block 406. With reference to block 406 of FIG. 4A, method 400 includes positioning the substrate and the mask relative to each other at each relative position in a first plurality of relative positions along the first direction, wherein a distance between adjacent relative positions in the first plurality of relative positions is equal to or less than the first dimension of any second mask portion in the one or more second mask portions. For instance, FIGS. 5B-5D show a portion of the mask (i.e., a second mask portion) and a corresponding portion of the substrate, and use them to illustrate positioning substrate 502 and mask 508 relative to each other at each relative position along the x-direction, where M is any integer greater than 1. The positioning of the substrate and the mask relative to each other can be achieved by moving the substrate, or the mask, or both of the substrate and the mask. In some exemplary embodiments, the positioning of the substrate and the mask relative to each other is performed successively and/or stepwise.

In the illustrated embodiment, a distance between adjacent relative positions in the first plurality of relative positions is represented by the distance of an edge of a second mask portion at two adjacent positions. For instance, dx₁ represents the distance between the first and second relative positions in the x-direction, and dx₂ represents the distance between the second and third relative positions in the x-direction. Each distance dxₘ, where mϵ[1, M−1], is equal to or less than first dimension Wx of any second mask portion 512 of mask 508. Each distance dxₘ, however, can be the same as or different from any other distances along the x-direction. For instance, dx₁ can be the same as or different from dx₂. In some exemplary embodiments, at least two distances between adjacent relative positions in the first plurality of relative positions are the same as each other. In some exemplary embodiments, at least two distances between adjacent relative positions in the first plurality of relative positions are different from each other. As a non-limiting example, FIGS. 5B-5D illustrate a uniform stepping, i.e., all distances dxₘ, where mϵ[1, M−1], are substantially the same. In some exemplary embodiments, a distance between adjacent relative positions in the first plurality of relative positions is between 0.1 μm and 1 μm, between 1 μm and 10 μm, between 10 μm and 20 μm, or between 20 μm and 30 μm.

In some exemplary embodiments, a distance between any two relative positions in the first plurality of relative positions is equal to or less than the first dimension of any second mask portion in the one or more second mask portions. For instance, in the illustrated embodiment, the distance between the first and any other relative positions (e.g., 2^{nd}, 3^{rd}, . . . , or M^{th} relative position) in the x-direction are all less than first dimension Wx of any second mask portion 512 of mask 508.

Block 408. With reference to block 408 of FIG. 4A, method 400 includes exposing, at each respective relative position in the first plurality of relative positions, the first polymer layer through the mask to a corresponding dose in a first plurality of doses of the radiation, thereby producing one or more first exposed polymer portions in the first polymer layer. For instance, at the first relative position along the x-direction (e.g., the position indicated by 512_{x,1}), the first polymer layer is exposed to first dose r_{x,1} of the radiation through the mask. At the second relative position along the x-direction (e.g., the position indicated by 512_{x,2}), the first polymer layer is exposed to second dose r_{x,2} of the radiation through the mask. At the M^{th} relative position along the x-direction (e.g., the position indicated by 512_{x,M}), the first polymer layer is exposed to M^{th} dose r_{x,M} of the radiation through the mask. Doses can be the same as or different from each other. For instance, dose r_{x,1} can be the same as or different from dose r_{x,2}. In some exemplary embodiments, doses r_{x,m}, where m=1, 2, . . . , M, are precisely controlled, for instance, by controlling the intensity of the radiation and/or the duration at the relative positions.

Corresponding to each second mask portion, the exposure of the radiation along the x-direction produces a first exposed polymer portion such as exposed polymer portion 514 illustrated in FIGS. 5C-5E. Exposed polymer portion 514 includes a plurality of exposed segments such as 516_{x,1}, 516_{x,2}. The dose received at each segment after the exposure of the first polymer at each of M relative positions along the x-direction is represented by:

$${R}_{x , m} = \{ \begin{matrix}{\sum }_{i = 1}^{m} {r}_{x , i} & m \leq M \\ {\sum }_{i = 1}^{M} {r}_{x , i} - {\sum }_{i = M + 1}^{m} {r}_{x , i - M} & m > M\end{matrix} \qquad Eq . ( 1 )$$

Block 410. With reference to block 410 of FIG. 4A, method 400 includes positioning the substrate and the mask relatively to each other at each relative position in a second plurality of relative positions along the second direction, wherein a distance between adjacent relative positions in the second plurality of relative positions is equal to or less than the second dimension of any second mask portion in the one or more second mask portions.

The positioning of the substrate and the mask relatively to each other at each relative position along the second direction can be performed in a similar manner as the positioning of the substrate and the mask relatively to each other at each relative position along the first direction disclosed herein. For instance, similar to the positioning of the substrate and the mask relatively to each other along the first direction, each distance dyₙ between adjacent relative positions in the y-direction, wherein nϵ[1, N−1], is equal to or less than second dimension Wy of any second mask portion 512 of mask 508. Also similar to the positioning of the substrate and the mask relatively to each other along the first direction, each distance dyₙ can be the same as or different from any other distance along the y-direction.

A distance between adjacent relative positions along the second direction can be the same as a distance adjacent relative positions along the first direction (e.g., to make an etalon with a square shape), or different from a distance adjacent relative positions along the first direction (e.g., to make an etalon with a rectangular shape). In some exemplary embodiments, a distance between adjacent relative positions in the second plurality of relative positions is between 0.1 μm and 1 μm, between 1 μm and 10 μm, between 10 μm and 20 μm, or between 20 μm and 30 μm. In some exemplary embodiments, the first relative position for starting the positioning along the second direction coincides with the first relative position for starting the positioning along the first direction.

In an exemplary embodiment, the positioning of the substrate and the mask relatively to each other along the second direction is performed subsequent to the positioning of the substrate and the mask relatively to each other along the first direction. In an alternative exemplary embodiment, the positioning of the substrate and the mask relatively to each other along the second direction is performed prior to the positioning of the substrate and the mask relatively to each other along the first direction.

Block 412. With reference to block 412 of FIG. 4B, method 400 includes exposing, at each respective relative position in the second plurality of relative positions, the first polymer layer through the mask to a corresponding dose in a second plurality of doses of the radiation, thereby producing one or more second exposed polymer portions in the first polymer layer. Each respective second exposed polymer portion in the one or more second exposed polymer portions overlaps at least partially with each corresponding first exposed polymer portion in the one or more first portions, thereby producing one or more overlapped exposed polymer portions, each overlapped exposed polymer portion creates an array of dosed segments, wherein each dosed segment in the array of dosed segments is exposed to a different dose of the radiation.

The exposing of the first polymer at each respective relative position along the second direction can be performed in a similar manner as the exposing of the first polymer at each respective relative position along the first direction disclosed herein. For instance, at the first relative position along the y-direction, the first polymer layer is exposed to first dose r_{y,1} of the radiation through the mask. At the second relative position along the y-direction, the first polymer layer is exposed to second dose r_{y,2} of the radiation through the mask. At the N^{th} relative position along the y-direction, the first polymer layer is exposed to N^{th} dose r_{y,1} of the radiation through the mask. Doses r_{y,n}, where n=1, 2, . . . , N, can be the same as or different from each other, and can be precisely controlled, for instance, by controlling the intensity of the radiation and/or the duration at the relative positions.

Corresponding to each second mask portion, the exposure of the radiation along the y-direction produces a second exposed polymer portion such as exposed polymer portion 518 illustrated in FIG. 5G. Corresponding to each second mask portion, second exposed polymer portion 518 overlaps at least partially with first exposed polymer portion 514, thereby producing an overlapped exposed polymer portion such as overlapped exposed polymer portion 520 illustrated in FIG. 5G. Overlapped exposed polymer portion 520 includes an array of dosed segments.

In some exemplary embodiments, the first relative position in the second plurality of relative positions coincides with the first relative position in the first plurality of relative positions. For instance, after the positing and exposing along the x-direction, the mask and/or substrate are moved back to their initial positions before starting the positing and exposing along the y-direction. In the embodiments where the first relative position in the second plurality of relative positions coincides with the first relative position in the first plurality of relative positions, the dose received at each segment 522_{m,n} after the exposure of the first polymer for M times along the x-direction and N times along the y-direction is represented by:

$$\begin{matrix}{R}_{m , n} = {\sum }_{i = 1}^{m} {r}_{x , i} + {\sum }_{j = 1}^{n} {r}_{y , j} & m \leq M , n \leq N\end{matrix} \qquad Eq . ( 2 )$$

In some exemplary embodiments, doses are controlled such that each dosed segment in the array of dosed segments is exposed to a different dose of the radiation. That is, R_{m,n} for segment 522_{m,n}, where m≤M, n≤N, is unique and different from the doses received at other segments in the array. In some exemplary embodiments, doses are controlled through the control of the radiation intensity, the duration of the exposure, the number of the times each dosed segment is exposed to the radiation, or any combination thereof.

Corresponding to each second mask portion, the dosed received at non-overlapped portion is represented by:

$${R}_{i , j} = \{ \begin{matrix}{\sum }_{j = 1}^{N} {r}_{y , j} - {\sum }_{j = N + 1}^{n} {r}_{y , j - N} & m \leq M , n > N \\ {\sum }_{i = 1}^{M} {r}_{x , i} - {\sum }_{i = M + 1}^{m} {r}_{x , i - M} & m > M , n \leq N \\ 0 & m > M , n > N\end{matrix} \qquad Eq . ( 3 )$$

It should be noted that it is not necessary for the first relative position in the second plurality of relative positions to coincide with the first relative position in the first plurality of relative positions. For instance, in some exemplary embodiments, the first relative position in the second plurality of relative positions resides within or outside of the first exposed polymer portion 514.

Block 414. With reference to block 414 of FIG. 4B, in some exemplary embodiments, method 400 includes developing the first polymer layer of the substrate such that of each overlapped or final exposed polymer portion, each dosed segment in the array of dosed segments is developed to produce a first surface at a different depth in the first polymer layer, thereby creating one or more patterned structures in the first polymer layer of the substrate, each patterned structure comprising an array of first surfaces at different depths. For instance, in some exemplary embodiments, a developer including but not limited to aqueous bases is applied to the first polymer layer to remove the exposed polymer portions. Of each overlapped exposed polymer portion 520, each dosed segment 522_{m,n} is developed (e.g., removed) to produce a first surface such as first surface 526_{m,n} where mϵ[1, M] and nϵ[1, N]. Each first surface 526_{m,n} has a unique and different depth such as depth Ls_{m,n}. Corresponding to each overlapped exposed polymer portion 520, the array of first surfaces 526_{m,n} where mϵ[1, M] and nϵ[1, N] collectively forms a patterned structure such as patterned structure 524 in the first polymer layer of the substrate.

In some exemplary embodiments, of one or each patterned structure, the depths of the array of first surfaces range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm. In some exemplary embodiments, of one or each patterned structure, at least two depths of the array of first surfaces differ from each other by at least two orders of magnitude, or by at least three orders of magnitude. For instance, in an exemplary embodiment, the depths of the first surfaces of a patterned structure range from sub-100 nm to greater than 100 μm.

Of one or each patterned structure, the increments of the depths of the first can be uniform (e.g., along the first and/or second directions), non-uniform (e.g., different for at least two first surface along the first and/or second directions), or arbitrary. In some exemplary embodiments, the increment of the depths of the first surfaces is in the range of tens of nanometers.

Block 416. With reference to block 416 of FIG. 4B, in some exemplary embodiments, method 400 includes depositing a layer of a first reflective material on top of the one or more patterned structures. For instance, as a non-limiting example, FIG. 5H illustrates deposition of a layer of first reflective material 528 on top of the first surfaces of patterned structure 524. Examples of the first reflective material include but are not limited to aluminum or the like. In some exemplary embodiments, the layer of the first reflective material comprises a semi-transparent aluminum film having a thickness of between 5 and 10 nm, between 10 and 15 nm, between 15 and 20 nm, between 20 and 25 nm, or between 25 and 30 nm.

Block 418. With reference to block 418 of FIG. 4B, in some exemplary embodiments, optionally or additionally, method 400 includes overlaying a first protection layer on the layer of the first reflective material. For instance, as a non-limiting example, FIG. 5H illustrates overlaying first protection layer 530 on the layer of the first reflective material 528. Examples of the first protection layer include but are not limited to silicon dioxide (SiO2) or the like. In some exemplary embodiments, SiO2 is deposited by sputtering or evaporation at a low temperature (e.g., <100° C.) to preserve the integrity of the underlying layer(s).

Block 420. With reference to block 420 of FIG. 4B, in some exemplary embodiments, optionally or additionally, method 400 includes overlaying a second protection layer on the first protection layer. For instance, as a non-limiting example, FIG. 5H illustrates overlaying second protection layer 532 on first protection layer 530. Examples of the second protection layer include but not limited to polymers or the like.

Block 422. With reference to block 422 of FIG. 4B, in some exemplary embodiments, method 400 includes dicing the substrate to produce one or more individual chips, each comprising a patterned structure in the one or more patterned structures. For instance, in embodiments where there are multiple second mask portions, the substrate is diced to produce multiple individual chips (e.g., between 10 and 50, between 50 and 100, between 100 and 150, between 150 and 200, between 200 and 300, between 300 and 400, or between 400 and 500 individual chips). Each individual chip comprises a patterned structure such as patterned structure 524.

In some exemplary embodiments, substrate 502 comprises glass substrate 534 coated with a layer second reflective material 536 as illustrated in FIGS. 5A and 5H. The layer of second reflective material 536 can be the same as or different from the layer of first reflective material 528 in terms of the material and the thickness of the layer. Examples of the second reflective material include but are not limited to aluminum. In some exemplary embodiments, the layer of the second reflective material comprises a semi-transparent aluminum film having a thickness of between 5 and 10 nm, between 10 and 15 nm, between 15 and 20 nm, between 20 and 25 nm, or between 25 and 30 nm.

In some exemplary embodiments, first polymer layer 504 overlays the layer of second reflective material 536. As such, corresponding to each patterned structure (e.g., each individual chip after the dicing), the second reflective layer formed by the layer of second reflective material 536, the first reflective layer formed by the layer of first reflective material 528, and first polymer layer 504 in-between the first and second reflective layers collectively form an optical array such as optical array 538 (e.g., a large etalon array).

Block 424. With reference to block 424 of FIG. 4B, in some exemplary embodiments, additionally or optionally, method 400 includes attaching a sensor array above or under each of the one or more patterned structures, wherein the sensor array is configured to detect light transmitted through the optical array. For instance, as a non-limiting example, FIG. 5H illustrates attaching sensor array 540 to substrate 502 under patterned structure 524. In an exemplary embodiment, the attaching of the sensor array is performed prior to the dicing of the substrate. In another exemplary embodiment, the attaching of the sensor array is performed subsequent to the dicing of the substrate. In some exemplary embodiments, the sensor array is glued to the substrate by an adhesive.

Sensor array 540 is configured to detect light transmitted through optical array 538. It can be any suitable detectors including but not limited to a photon detector, a thermal detector, or any combination thereof. In some exemplary embodiments, the sensor array includes a photon detector such as a charge-coupled device (CCD), a complementary metal-oxide semiconductor (CMOS), an Indium Gallium Arsenide (InGaAs) photodiode detector, a Germanium (Ge) photodiode detector, a Mercury Cadmium Telluride (MCT) array, or the like, or any combination thereof. In some exemplary embodiments, the sensor array includes a thermal detector comprising a microbolometer array, or a microthermocouple array, or any combination thereof.

To further illustrate the method of fabricating large etalon arrays and optical devices having large etalon arrays, listed below are some exemplary processes. In some exemplary embodiments, to make large etalon arrays and optical devices having large etalon arrays:
Glass substrate is cleaned with Acetone, IPA, DI water, or the like.
Glass substrate is coated with a reflective film (e.g., Al film of about 15 nm) and then with adhesion promoter layer to increase the adhesion of the polymer to the glass substrate.
A polymer layer (e.g., PMMA A11 film of 5-10 microns) is spun on top of glass substrate using spin coater. The maximum thickness that can be achieved using PMMA A11 using a single spin coat at 1000 rpm spin speed is about 4 microns.
The spin coated film is left to bake in hot plate (e.g., at 180° C. for about 2 minutes) and left to cool down slowly (e.g. overnight) to room temperature to avoid formation of stress cracks.
The layer is then exposed by a beam of radiation whereby the dose deposited in the polymer (e.g., PMMA) layer is controlled and varied locally across the polymer (e.g., PMMA) surface.
To control the dose deposited during exposure, a mask (e.g., 4-inch diameter mask with 148 square holes of 2.4×2.4 mm² each) is placed on top of a movable wafer beneath. High-precision micro-stages control the lateral movement of the wafer in relation to the mask.
To achieve an etalon array of M by N (e.g., 32 by 32) square fields (e.g., totaling 1024 etalons), the wafer is scanned stepwise in a rectangular grid by two orthogonally arranged linear micro-stages (e.g. describing a X and Y coordinate system). Either the X or the Y direction may be scanned stepwise, first. Once an exposure direction is completed (e.g. by 32 steps), the respective micro-stage moves back into its starting position after which the second direction is scanned. Both directional scans together yield overlapping exposure fields of M by N (e.g. 32 by 32) individual exposures, yet at M by N (e.g., 1024) exposure levels.
A subsequent development step yields a 3D pattern of varying depth profile that follows the deposited dose profile.
A reflective layer (e.g., 15 nm of Al) is deposited on top of patterned three-dimensional chessboard architecture.
The wafer is then diced using laser or saw, to cut it into individual chips (e.g., 148 individual chips).

It should be noted that these processes are non-limiting, non-inclusive, and non-exclusive. For instance, in some exemplary embodiments, a method of fabricating large etalon arrays and optical devices having large etalon arrays does not include all of these processes, and in some other exemplary embodiments, a method of fabricating large etalon arrays and optical devices having large etalon arrays includes alternative, additional or optional processes

II-2. Exemplary Method 600

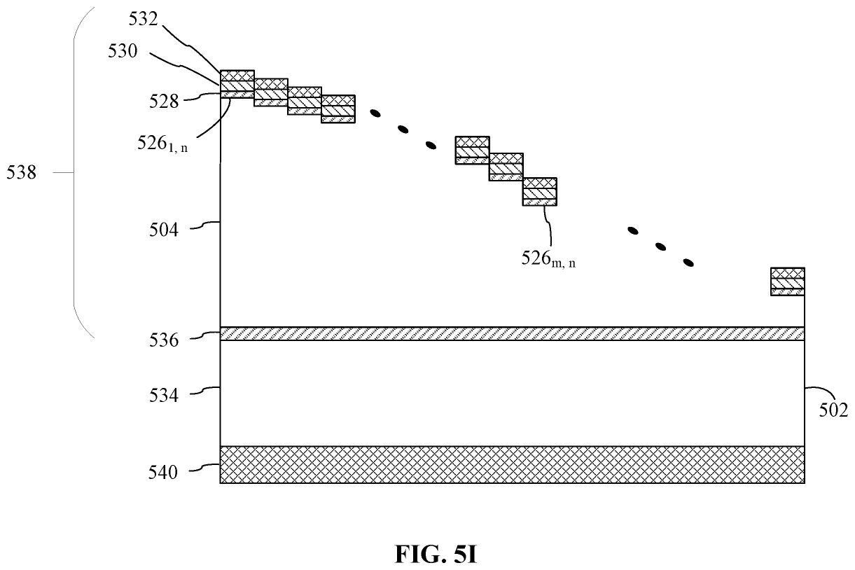

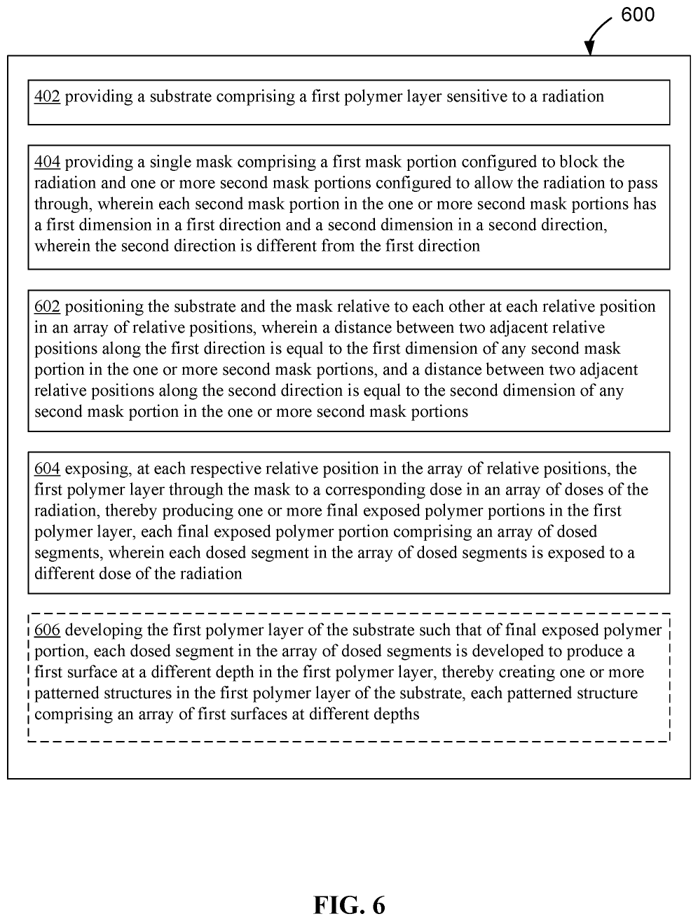

FIG. 6 illustrates a flow chart describing exemplary method 600 for manufacturing large etalon arrays and optical devices having larger etalon arrays in accordance with some exemplary embodiments of the present disclosure. Like method 400, method 600 in general includes irradiating a polymer layer through a single mask with one or more second mask portions. However, unlike method 400, the one or more second portions are configured and movement of the substrate and/or mask is controlled such that no substantive overlapping is created during the exposure of the first polymer layer to the radiation. Accordingly, the dose is controlled by controlling the duration of the exposure and intensity of the radiation. The exposed polymer layer is then developed (e.g., using a wet chemistry), thereby creating a three-dimensional topography in the polymer layer. In some exemplary embodiments, two reflective layers are deposited and a wafer is subsequently diced to produce individual chips each including a large etalon array.

Block 602. With reference to block 602 of FIG. 6, method 600 includes providing a substrate comprising a first polymer layer sensitive to a radiation. This is essentially the same as block 402 as disclosed herein with respect to method 400.

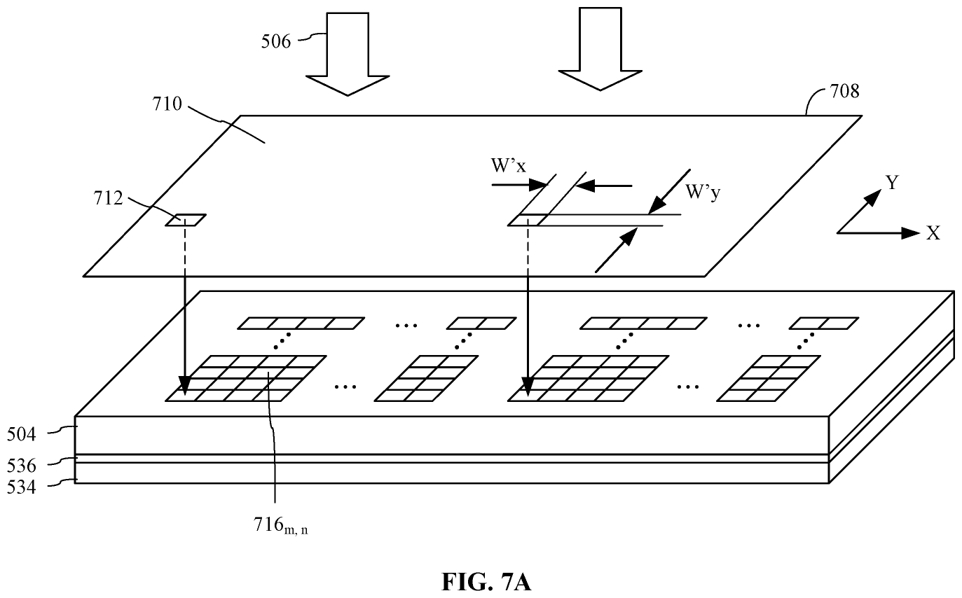

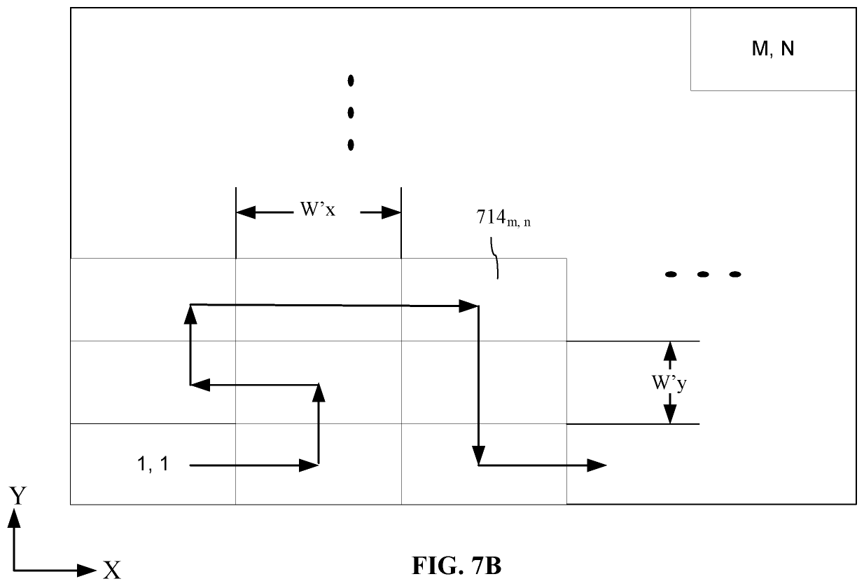

Block 604. With reference to block 602 of FIG. 6, method 600 includes providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction. This is similar to block 404 as disclosed herein with respect to method 400, except each second mask portion has a relatively smaller size compared to second portion 512. For instance, as a non-limiting example, FIG. 7A illustrates mask 708 comprising first mask portion 710 and two second mask portions 712. While two second mask portions are illustrated in FIG. 7A, it should be noted that mask 708 can include a single second mask portion, or as many as tens, hundreds or thousands of second mask portions. For instance, like mask 508, mask 708 can include between 10 and 50, between 50 and 100, between 100 and 150, between 150 and 200, between 200 and 300, between 300 and 400, or between 400 and 500 second mask portions that are spatially separated from another.

Second mask portion 712 has a characteristic first dimension in a first direction, e.g., first dimension W′x in the x-direction, and a characteristic second dimension in a second direction, e.g., second dimension W′y in the y-direction. W′x and W′y can be the same as or different from each other. In some exemplary embodiments, mask portion 712 has a size between 0.001×0.001 and 0.1×0.1 mm². In some exemplary embodiments, mask portion 712 is a pixelated hole, e.g., a hole having its shape and size matched with a pixel of a detector. In an exemplary embodiment, the first or second dimension is substantially 1.7 μm, 2.2 μm, 3.5 μm, 4.6 μm, 6.5 μm, 7 μm, 10 μm, or 14 μm. In some exemplary embodiments, mask portion 712 has a size that matches with a cluster of pixels of a detector.

Block 606. With reference to block 606 of FIG. 6, method 600 includes positioning the substrate and the mask relative to each other at each relative position in an array of relative positions, wherein a distance between two adjacent relative positions along the first direction is equal to the first dimension of any second mask portion in the one or more second mask portions, and a distance between two adjacent relative positions along the second direction is equal to the second dimension of any second mask portion in the one or more second mask portions.

It should be noted that the term “equal to” used herein refers to the same or substantially the same within a toleration of precision. It should also be noted that an array of relative positions as used herein refers to a one-dimensional array, a two-dimensional array, or other patterns (e.g., circle, diamond, randomly arranged array). As a non-limiting example, FIG. 7B illustrates the positioning of the substrate and the mask relative to each other at each relative positions in a two-dimensional M×N array. The distance between two adjacent relative positions along the first direction is equal to first dimension W′x, and the distance between two adjacent relative positions along the second direction is equal to second dimension W′y.

In an exemplary embodiment, the positioning is performed successively and stepwise along a row (or column) of the array followed by another row (or column) of the array. In another exemplary embodiment, the positioning is performed zigzag, alternating between the x- and y-directions, for instance, as indicated by the arrows starting from relative position (1,1). In a further exemplary embodiment, the positioning is performed randomly across the array.

Block 608. With reference to block 608 of FIG. 6, method 600 includes exposing, at each respective relative position in the array of relative positions, the first polymer layer through the mask to a corresponding dose in an array of doses of the radiation, thereby producing one or more final exposed polymer portions in the first polymer layer, each final exposed polymer portion comprising an array of dosed segments, wherein each dosed segment in the array of dosed segments is exposed to a different dose of the radiation. For instance, at relative position 714_{m,n}, the first polymer layer is exposed to dose R_{m,n} of the radiation through the mask, where mϵ[1, M] and nϵ[1, N]. As such, corresponding to each second mask portion 712, the exposing of the first polymer layer through the mask creates a final exposed polymer portion with an array of dosed segments such as dose segments 716_{m,n}. Since the distance between two adjacent relative positions along the first direction is equal to first dimension W′x, and the distance between two adjacent relative positions along the second direction is equal to second dimension W′y, there is no overlapping or no substantive overlapping of exposure. In some exemplary embodiments, each dose R_{m,n} is unique and different from the doses at other relative positions. In other words, each dosed segment in the array of dosed segments is exposed to a different dose of the radiation.

Block 610. With reference to block 610 of FIG. 6, in some exemplary embodiments, method 600 includes developing the first polymer layer of the substrate such that of each final exposed polymer portion, each dosed segment in the array of dosed segments is developed to produce a first surface at a different depth in the first polymer layer, thereby creating one or more patterned structures in the first polymer layer of the substrate, each patterned structure comprising an array of first surfaces at different depths. This process is essentially the same as disclosed herein with references to block 414 of method 400.

After the developing of the first polymer layer of the substrate, method 600 can include other additional or optional processes. For instance, in some exemplary embodiments, method 600 includes (i) depositing a layer of a first reflective material on top of the one or more patterned structures as disclosed herein with reference to block 416, (ii) overlaying a first protection layer on the layer of the first reflective material as disclosed herein with reference to block 418, (iii) overlaying a second protection layer on the first protection layer as disclosed herein with reference to block 420, (iv) dicing the substrate to produce one or more individual chips as disclosed herein with reference to block 422, (v) attaching a sensor array above or under each of the one or more patterned structures as disclosed herein with reference to block 424, or any practical combination thereof.

II-3. Exemplary Method 800

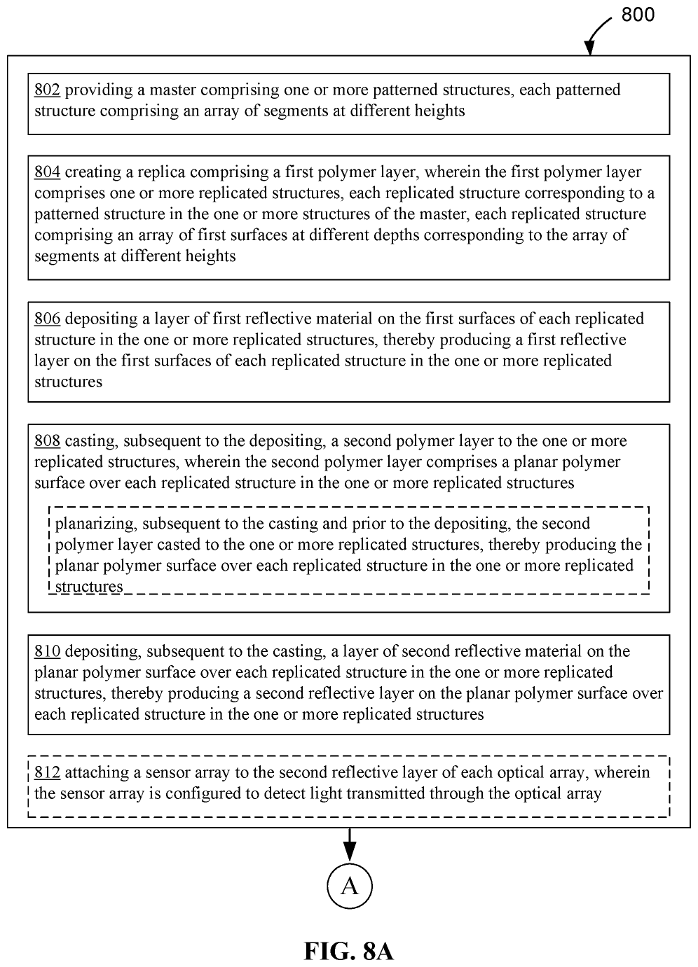

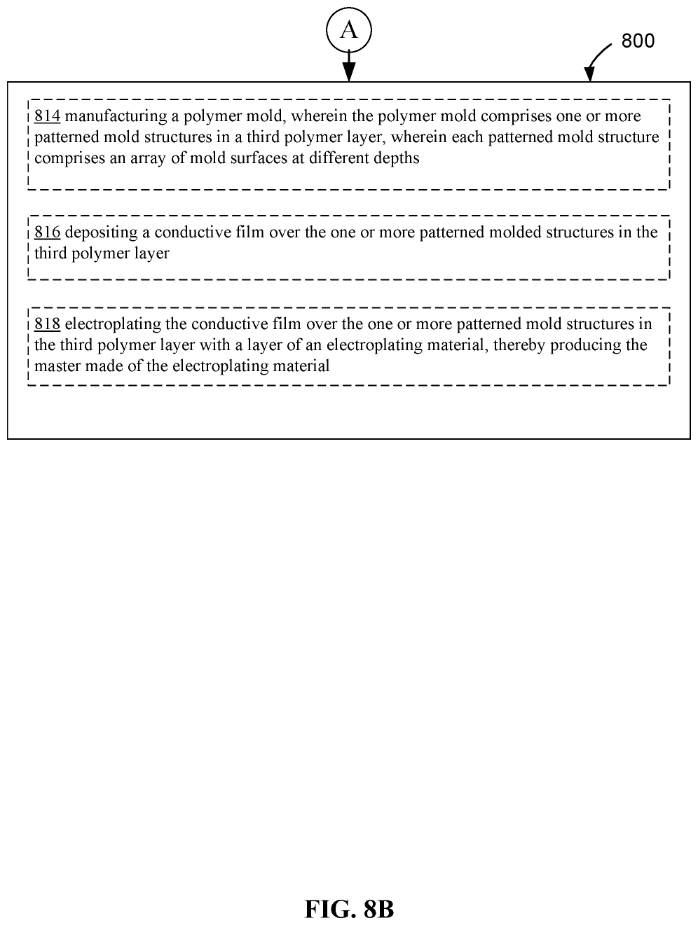

FIGS. 8A and 8B illustrate flow charts describing exemplary method 800 for mass replicating large etalon arrays and optical devices having larger etalon arrays in accordance with some exemplary embodiments of the present disclosure. Method 800 in general includes creating a replica of a master with one or more patterned structures. In some exemplary embodiments, a mold for mass replication is manufactured whereby a silicon wafer is first coated with a polymer layer and subsequently structured by method 400 or method 600 disclosed herein. After structuring, a conducting layer (e.g. Au or Cu) is deposited. The conducting layer then serves as a starting layer for electroplating a relatively thick metal layer, a negative of the thin structured polymer layer. The electroplated metal layer is removed from the silicon substrate and serves as the master for mass replication processes such as hot embossing or nano-imprinting or the like.

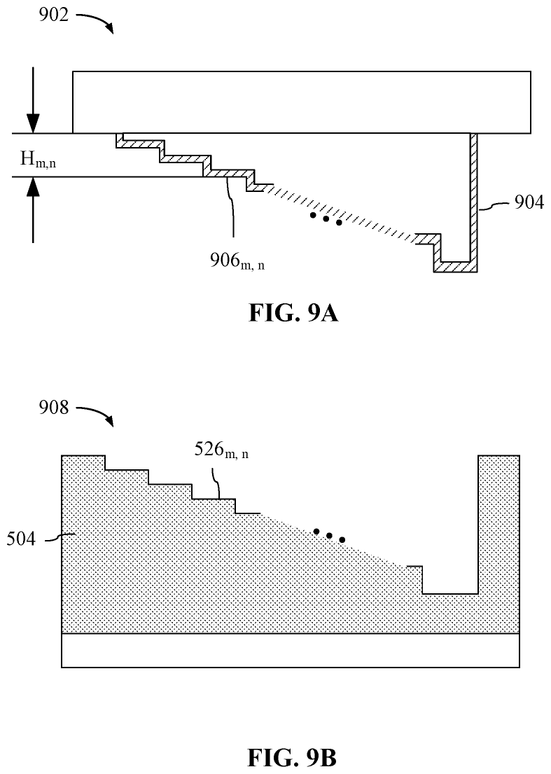

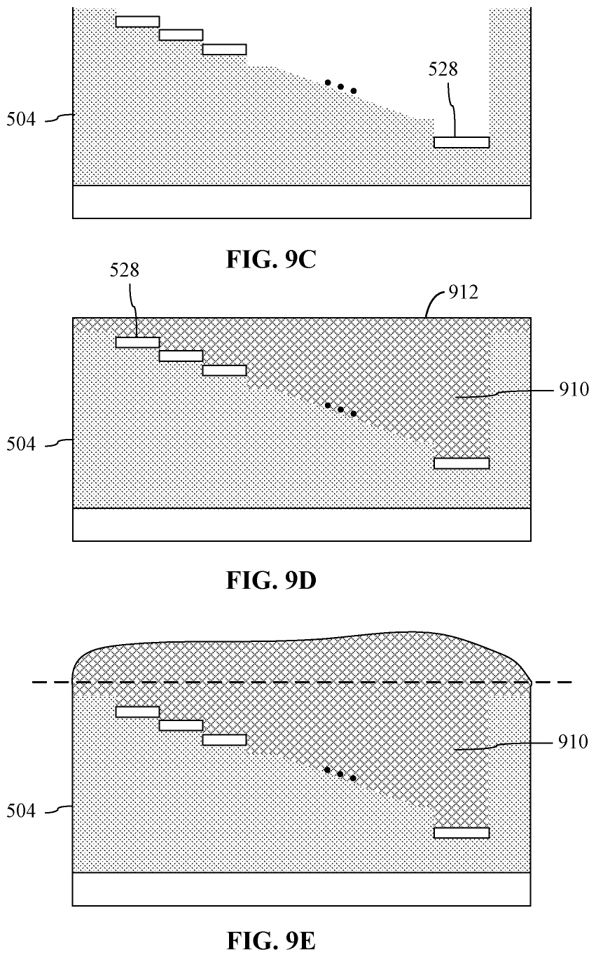

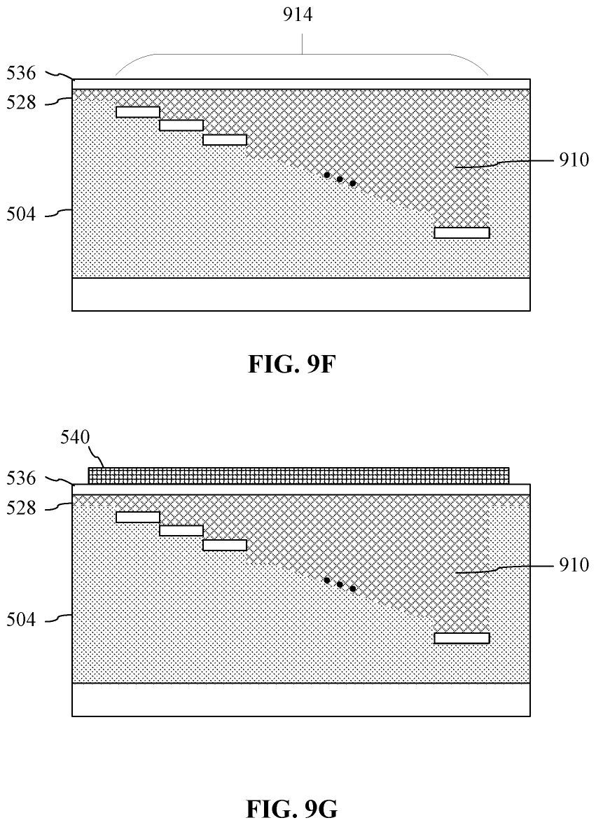

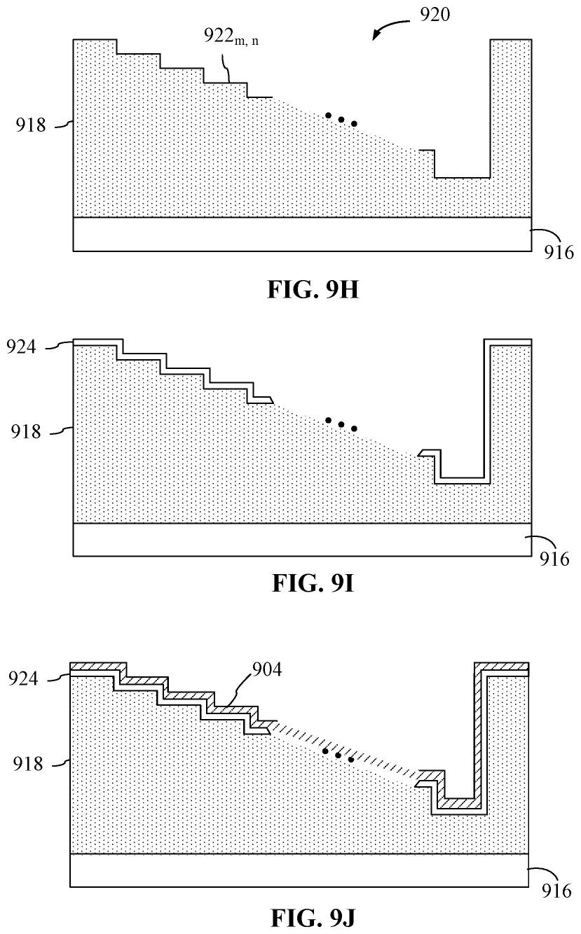

Block 802. With reference to block 802 of FIG. 8A, method 800 includes providing a master comprising one or more patterned structures, each patterned structure comprising an array of segments at different heights. For instance, as a non-limiting example, FIG. 9A illustrates master 902 comprising patterned structure 904. Patterned structure 904 comprises an array of segments such as segment 906_{m,n}. In some exemplary embodiments, the array of segments is an M×N array of segment 906_{m,n} with height H_{m,n}, where mϵ[1, M] and nϵ[1, N]. In some exemplary embodiments, each depth H_{m,n} is unique and different from the heights of other segments within the same array.

While FIG. 9A illustrates one patterned structure 904, it should be noted that master 902 can include more than one patterned structure. For instance, in some exemplary embodiments, master 902 includes between 10 and 50, between 50 and 100, between 100 and 150, between 150 and 200, between 200 and 300, between 300 and 400, or between 400 and 500 patterned structures that are spatially separated from each other. It should also be noted that patterned structures on the same master can have the same configuration or different configurations.

Block 804. With reference to block 804 of FIG. 8A, method 800 includes creating a replica comprising a first polymer layer, wherein the first polymer layer comprises one or more replicated structures, each replicated structure corresponding to a patterned structure in the one or more structures of the master, each replicated structure comprising an array of first surfaces at different depths corresponding to the array of segments at different heights. For instance, as a non-limiting example, FIG. 9B illustrates the creation of replicated structure 908 corresponding to pattern structure 902.

Replicated structure 908 comprises an array of first surfaces such as first surfaces 526_{m,n}. Corresponding to the array of segments at different heights, the array of first surfaces 526_{m,n} where mϵ[1, M] and nϵ[1, N] has different depths. In some exemplary embodiments, the depths of the array of first surfaces range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm. Of a respective replicated structure in the one or more replicated structures, at least two depths of the array of first surfaces differ from each other by at least two orders of magnitude, or by at least three orders of magnitude. In some exemplary embodiments, M is any integer between 1 and 5000, and N is any integer between 1 and 5000.

Block 806. With reference to block 806 of FIG. 8A, method 800 includes depositing a layer of first reflective material on the first surfaces of each replicated structure in the one or more replicated structures, thereby producing a first reflective layer on the first surfaces of each replicated structure in the one or more replicated structures. For instance, as a non-limiting example, FIG. 9C illustrates deposition of the layer of first reflective material 528 on the first surfaces of replicated structure 908.

Block 808. With reference to block 808 of FIG. 8A, method 800 includes casting, subsequent to the depositing of the layer of first reflective material, a second polymer layer to the one or more replicated structures, wherein the second polymer layer comprises a planar polymer surface over each replicated structure in the one or more replicated structures. For instance, as a non-limiting example, FIG. 9D illustrates the casting of second polymer layer 910 to replicated structure 908, and second polymer layer 910 has planar polymer surface 912. In some exemplary embodiments such as those illustrated in FIG. 9E, to make planar polymer surface 912, method 100 includes planarizing the second polymer layer casted to replicated structure 908 after the depositing of the second polymer layer 910. The planarizing of the second polymer layer can be performed by any suitable method including but not limited to chemical polishing, mechanical polishing, plasma etching, or any combination thereof.

The second polymer layer can comprise a material the same as the first polymer layer or different from the first polymer. In some exemplary embodiments, the second polymer layer comprises PMMA or the like.

Block 810. With reference to block 810 of FIG. 8A, method 800 includes depositing a layer of second reflective material on the planar polymer surface over each replicated structure in the one or more replicated structures, thereby producing a second reflective layer on the planar polymer surface over each replicated structure in the one or more replicated structures. For instance, as a non-limiting example, FIG. 9F illustrates the depositing of the layer of second reflective material to create second reflective layer 536 on planar polymer surface 912 over replicated structure 908. As such, corresponding to replicated structure 904, first reflective layer 528, second reflective layer 536 and second polymer layer 910 in-between the first and second reflective layers collectively form an optical array such as optical array 914 (e.g., a large etalon array). It should be noted that for a master comprising multiple patterned structures, method 800 will create multiple optical arrays, one optical array corresponding to each patterned structure.

Block 812. With reference to block 812 of FIG. 8A, in some exemplary embodiments, method 800 includes attaching a sensor array to the second reflective layer of each optical array, wherein the sensor array is configured to detect light transmitted through the optical array. For instance, as a non-limiting example, FIG. 9G illustrates attaching sensor array 540 to second reflective layer 536. In some exemplary embodiments, sensor array 540 is glued to second reflective layer 536 by an adhesive.

Block 814. With reference to block 814 of FIG. 8A, in some exemplary embodiments, additionally or optionally, method 800 includes manufacturing a polymer mold, wherein the polymer mold comprises one or more patterned mold structures in a third polymer layer, wherein each patterned mold structure comprises an array of mold surfaces at different depths. The polymer molded can be made by any suitable method including but not limited to method 400 and method 600 disclosed herein. The third polymer layer comprises a polymer material that can be the same as the first or second polymer layer, or different from the first or second polymer material.

For instance, as a non-limiting example, FIG. 9J illustrates polymer mold 916 comprising third polymer layer 918 and patterned mold structure 920. Patterned mold structure 920 includes an array of mold surfaces 922_{m,n}. While only one patterned structure is shown, it should be noted that polymer mold 916 can include more than one patterned structure. For instance, it can include tens or hundreds of patterned structures spatially separated from each other.

Block 816. With reference to block 816 of FIG. 8A, in some exemplary embodiments, method 800 includes depositing a conductive film over the one or more patterned molded structures in the third polymer layer. For instance, as a non-limiting example, FIG. 9K illustrates the depositing of conductive film 924 over patterned mold structure 920. In some exemplary embodiments, conductive film 924 is made of a material comprising gold (Au), Copper (Cu) or the like. The conducting layer then serves as a starting layer for electroplating a relatively thick metal layer, a negative of the thin structured polymer layer.

Block 818. With reference to block 818 of FIG. 8A, in some exemplary embodiments, method 800 includes electroplating the conductive film over the one or more patterned mold structures in the third polymer layer with a layer of an electroplating material, thereby producing the master made of the electroplating material. For instance, as a non-limiting example, FIG. 9L illustrates electroplating conductive film 924 over patterned mold structure 920 with a layer of an electroplating material. In some exemplary embodiments, the electroplating material comprises nickel (Ni) or the like. The electroplated metal layer is removed from the silicon substrate and serves as master 904 for mass replicating of optical arrays 914 (large etalon arrays).

II-4. Exemplary Method 1000

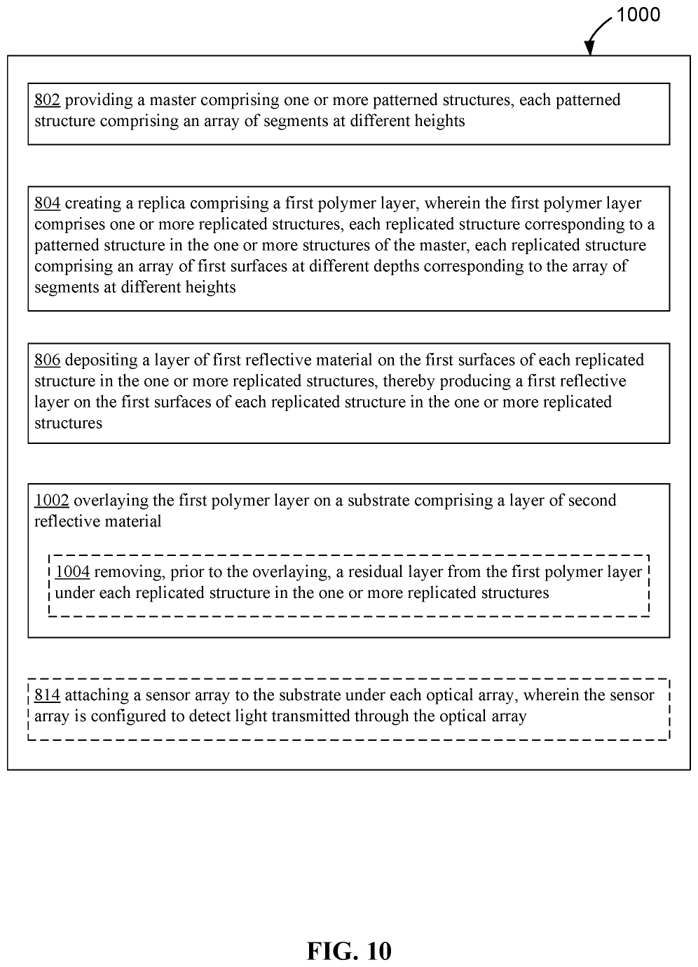

FIG. 10 illustrate a flow chart describing exemplary method 1000 for mass replicating large etalon arrays and optical devices having larger etalon arrays in accordance with some exemplary embodiments of the present disclosure. Like method 800, method 1000 in general includes creating a replica of a master that includes one or more patterned structures. For instance, method 1000 includes (i) providing a master comprising one or more patterned structures as disclosed herein with reference to block 802, (ii) creating a replica comprising a first polymer layer as disclosed herein with reference to block 804, and (iii) depositing a layer of first reflective material on the first surfaces of each replicated structure in the one or more replicated structures as disclosed herein with reference to block 806. In addition to these processes, method 1000 includes some alternative, optional or additional steps.

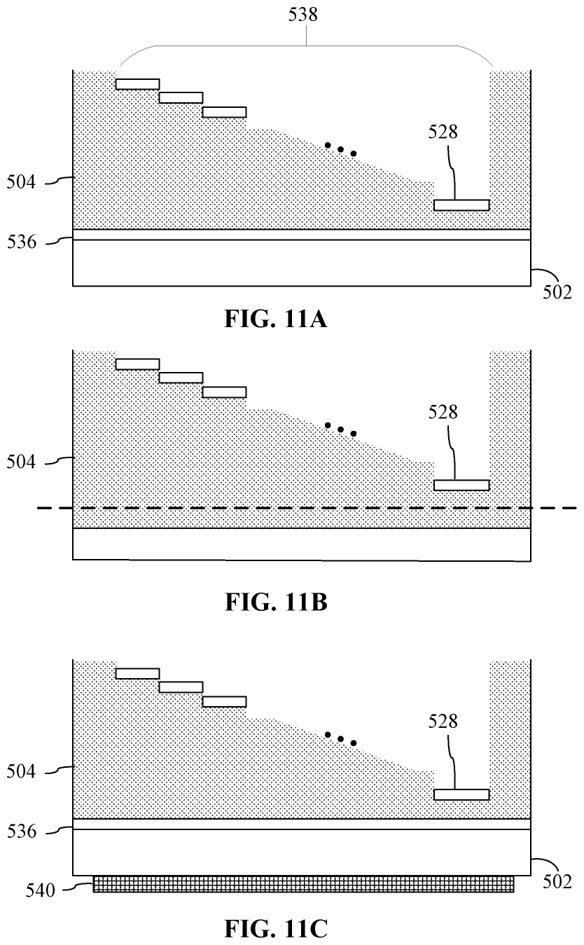

Block 1002. With reference to block 1002 of FIG. 10, method 1000 includes overlaying the first polymer layer on a substrate comprising a layer of second reflective material. For instance, as a non-limiting example, FIG. 11A illustrates overlaying first polymer layer 504 on substrate 502 which includes the layer of second reflective material (or second reflective layer) 536. In some exemplary embodiments, the first polymer layer is glued to the layer of second reflective material, for instance, by an adhesive or the like. In some exemplary embodiments, prior to the overlaying of the first polymer layer on the substrate, method 1000 includes removing a residual layer from the first polymer layer under each replicated structure in the one or more replicated structures as illustrated in FIG. 11B. The removing of the residual layer can be performed by reactive-ion etching or the like.

The overlaying of the first polymer layer can be performed either before or after the depositing of the layer of first reflective material 528. After the first polymer layer is overlaid on the substrate, first reflective layer 528, second reflective layer 536 and first polymer layer 504 in-between the first and second reflective layers collectively form an optical array such as optical array 538. While FIG. 11A illustrates one optical array 538, it should be noted that an optical array would be created corresponding to each replicated structure in the one or more replicated structures, which in turn corresponds to the one or more patterned structures of the master.

In some exemplary embodiments, method 1000 includes optional or additional processes. Examples of optional or additional processes include but are not limited to (i) overlaying a first protection layer on the first reflective layer as disclosed herein with reference to block 418, (ii) overlaying a second protection layer on the first protection layer as disclosed herein with reference to block 420, (iii) dicing the substrate to produce one or more individual chips as disclosed herein with reference to block 422, (iv) attaching a sensor array to the substrate under each optical array as disclosed herein with reference to block 424, (v) manufacturing a polymer mold as disclosed herein with reference to block 814, (vi) depositing a conductive film over the one or more patterned molded structures in the third polymer layer as disclosed herein with reference to block 816, and/or (vii) electroplating the conductive film over the one or more patterned mold structures in the third polymer layer with a layer of an electroplating material as disclosed herein with reference to block 818. These processes, along with the other processes of method 1000, can be performed in any suitable and practical combination and in any suitable and practical orders. As a non-limiting example, FIG. 11C illustrates the attaching of sensor array 540 to substrate 502 under optical array 538.

III. Exemplary Filter Arrays with Replicated Etalon Units

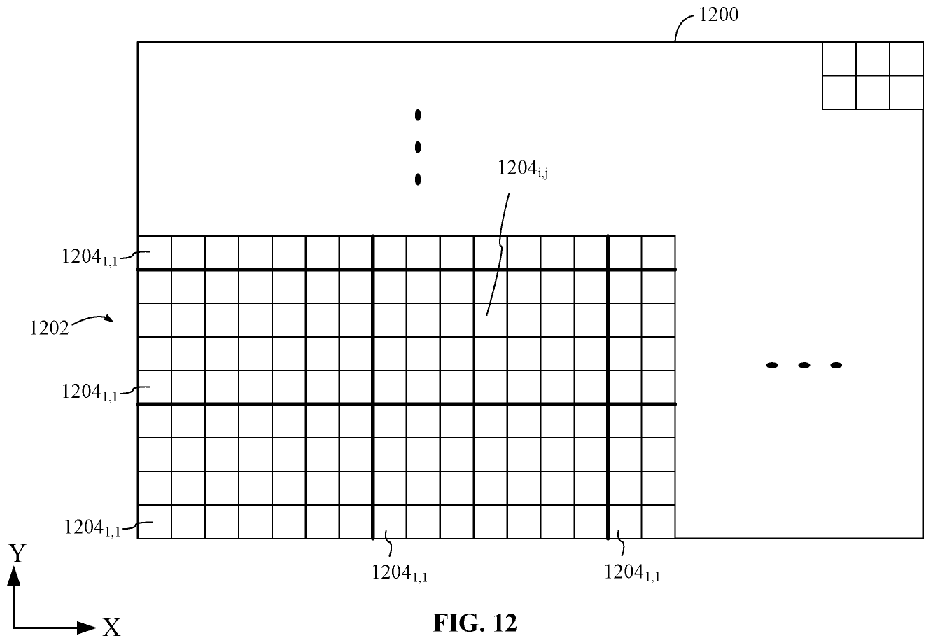

FIG. 12 illustrates exemplary filter array 1200 of the present disclosure in accordance with some embodiments. Filter array 1200 includes an array of etalon units such as etalon unit 1202. In some exemplary embodiments, filter array 1200 comprises at least tens, hundreds, thousands of etalon units arranged in a one-dimensional array, a two-dimensional array, or an arbitrary array. Each etalon unit is configured the same as the other etalon units, and includes an array of etalons such as etalon 1204. In some exemplary embodiments, each etalon unit 1202 includes between 5 and 10, between 10 and 20, between 30 and 40, between 40 and 50, or between 50 and 100 etalons arranged in a one-dimensional array, a two-dimensional array, or an arbitrary array. As a non-limiting example, FIG. 12 illustrates a two-dimensional array of etalon units 1202, each comprising a two-dimensional array of etalons 1204.

Of each etalon unit, at least two etalons in the array of etalons have different depths. In some exemplary embodiments, two or more etalons in the array of etalons have the same depth. In an exemplary embodiment, each etalon in the array of etalons have a unique and different depth. As such, when impinged by a light, each etalon of each etalon unit will generate a different transmission pattern.

In some exemplary embodiments, each etalon of etalon unit 1202 is configured such that the transmission pattern through each etalon contains a single peak, e.g., each etalon functions as an optical bandpass filter. This can be achieved by adjusting the depths of etalons, selecting appropriate reflective materials, and/or selecting appropriate materials between the two reflective layers of etalons. For instance, a typical etalon has resolution and free spectral range (FSR) defined by the distance between the two reflective layers (L) and the reflectivity of the two reflective layers. The distance between adjacent transmission resonances is free spectral range (FSR) and is given as FSR=λ²/2nL where λ is the wavelength of light and n is the refractive index of the material separating the two reflective layers. The resolution of the etalon unit is defined by the full-width at half-maximum (FWHM) of the transmission resonance and, in some case, can be described by dR=FSR*(1−R)/(π*\sqrt{R}), whereby R denotes the spectral reflectivity of the surfaces of the two reflective layers. Larger distance L results in higher resolution at the expense of narrower operating range or FSR. As such, with appropriate L, n and/or R, each etalon can be configured to transmit a specifically desired resonance of the incoming light.

In some exemplary embodiments, the depths of etalon units 1202 range from 100 nm to 300 nm, from 200 nm to 400 nm, from 300 nm to 500 nm, from 400 nm to 800 nm, from 500 nm to 1000 nm, from 200 nm to 1000 nm, from 200 nm to 1500 nm, from 100 nm to 1500 nm, or from 100 nm to 2000 nm.

While in FIG. 12 illustrated etalon 1204 has a substantially square shape, it should be noted that etalon 1204 can have any suitable shapes in the plane perpendicular to the depths (e.g., in the x-y plane) including but not limited to rectangle, circle, oblong, polygon, or the like. Etalon 1204 can also have any suitable sizes. In some exemplary embodiments, etalon 1204 has a size that is between 0.1×0.1 μm² and 1×1 μm², between 1×1 μm² and 10×10 μm², between 10×10 μm² and 20×20 μm², or between 20×20 μm² and 30×30 μm². In an exemplary embodiment, etalon 1204 has a size that matches with a pixel of the detector to be used for detecting the transmitted light. In another exemplary embodiment, etalon 1204 has a size that matches with a cluster of pixels of the detector to be used for detecting the transmitted light.

IV. Exemplary Method for Fabricating Filter Arrays with Replicated Units and Optical Devices Having Filter Arrays with Replicated Units

IV-1. Exemplary Method 1300

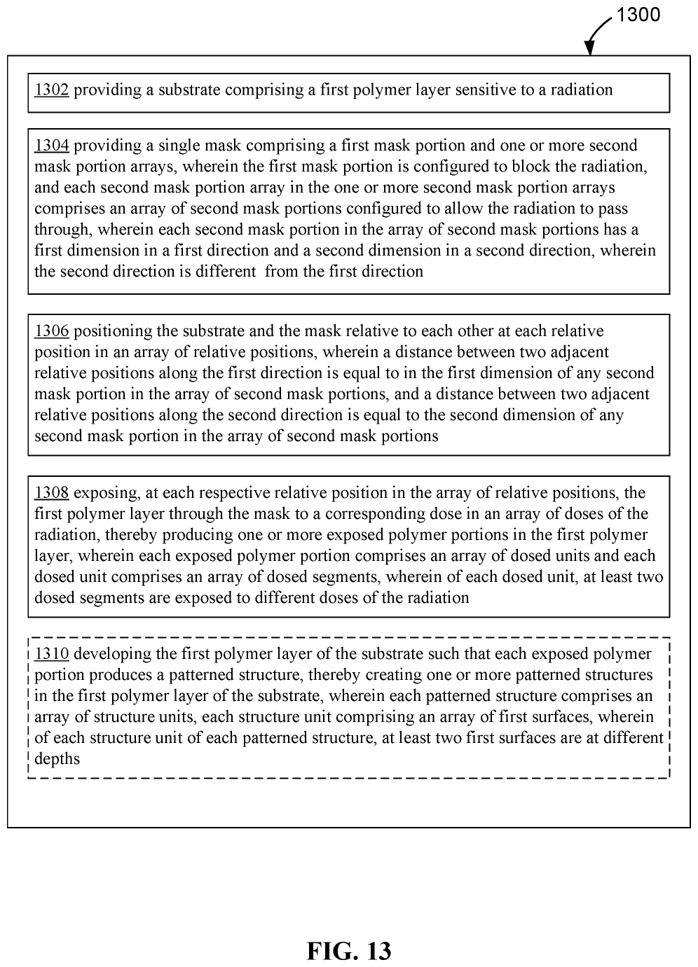

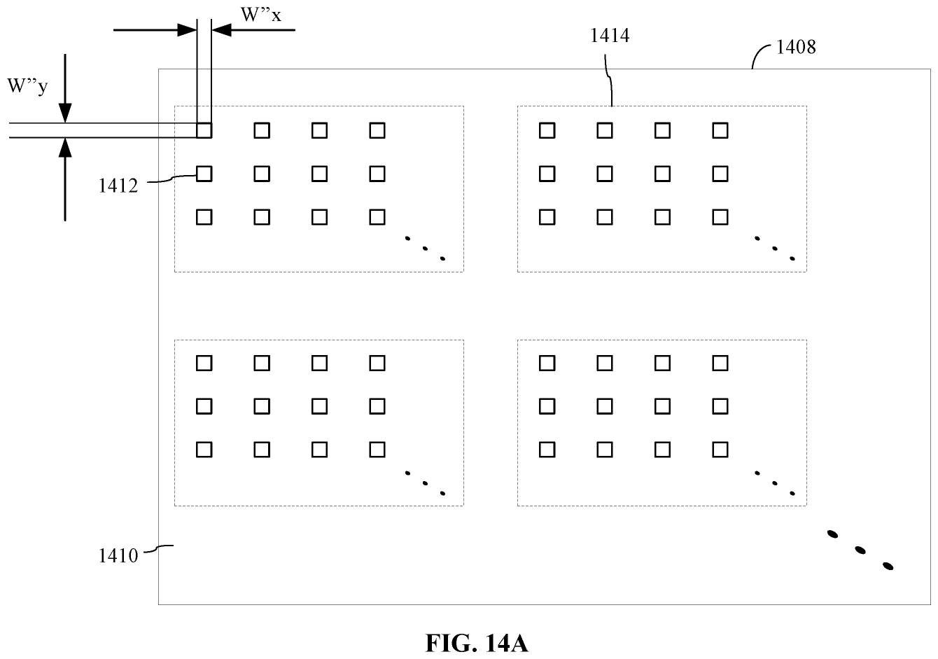

FIG. 13 illustrates a flow chart describing exemplary method 1300 for manufacturing filter arrays with replicated etalon units in accordance with some exemplary embodiments of the present disclosure. Method 1300 can be performed by a lithographic apparatus such that those disclosed in U.S. Pat. No. 9,400,432, which is incorporated herein by reference in its entirety for all purposes. Like method 600, method 1300 in general includes irradiating a polymer layer through a single mask and movement of the substrate or mask is controlled such that no substantive overlapping is created during the exposure of the first polymer layer to the radiation. Accordingly, the dose is controlled by controlling the duration of the exposure and/or intensity of the radiation. The exposed polymer layer is then developed (e.g., using a wet chemistry), thereby creating a three-dimensional topography in the polymer layer. In some exemplary embodiments, two reflective layers are deposited and a wafer is subsequently diced to produce individual chips each including a large etalon array.

Block 1302. With reference to block 1302 of FIG. 13, method 1300 includes providing a substrate comprising a first polymer layer sensitive to a radiation. This process is essentially the same as disclosed herein with references to block 402 of method 400, and with reference to block 602 of method 600.

Block 1304. With reference to block 1304 of FIG. 13, method 1300 includes providing a single mask comprising a first mask portion and one or more second mask portion arrays. The first mask portion is configured to block the radiation. Each second mask portion array in the one or more second mask portion arrays comprises an array of second mask portions configured to allow the radiation to pass through. In some exemplary embodiments, the mask comprises tens or hundreds of second mask portion arrays arranged in a one-dimensional array, a two-dimensional array, or an arbitrary array, and each second mask portion array comprises tens, hundreds, or thousands of second mask portions arranged in a one-dimensional array, a two-dimensional array, or an arbitrary array. For instance, in some exemplary embodiments, a mask comprises between 10 and 50, between 50 and 100, between 100 and 150, between 150 and 200, between 200 and 300, between 300 and 400, or between 400 and 500 second mask portion arrays, wherein each second mask portion array is spatially separated from others. In some exemplary embodiments, each second mask portion array comprises between 10 and 100, between 100 and 200, between 200 and 500, between 500 and 1000, between 1000 and 2000, between 2000 and 5000, or between 5000 and 10000 second mask portions, wherein each second mask portion is spatially separated from others.

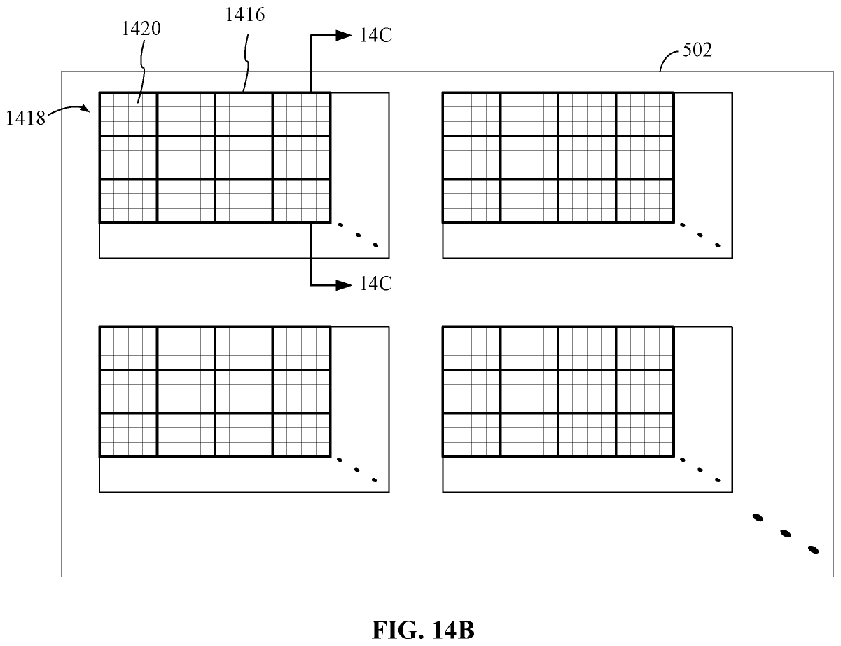

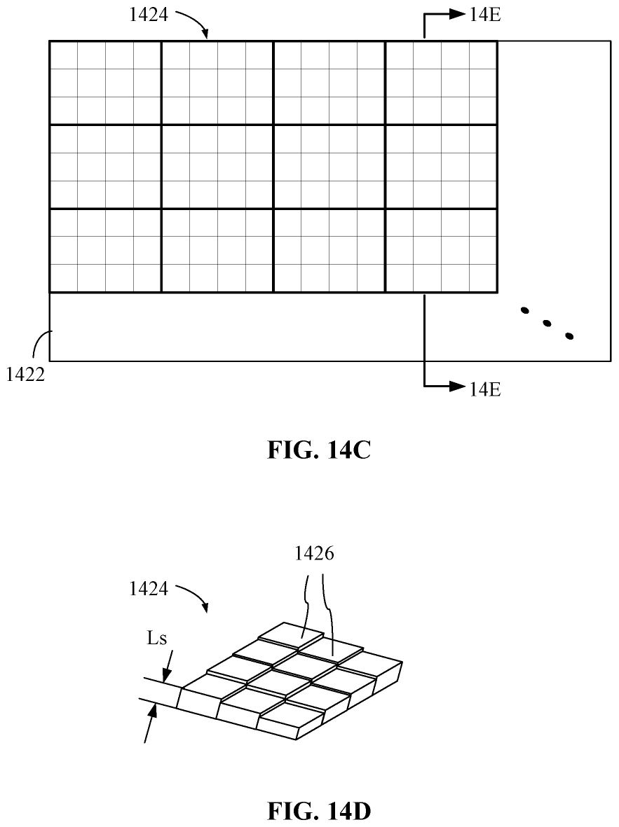

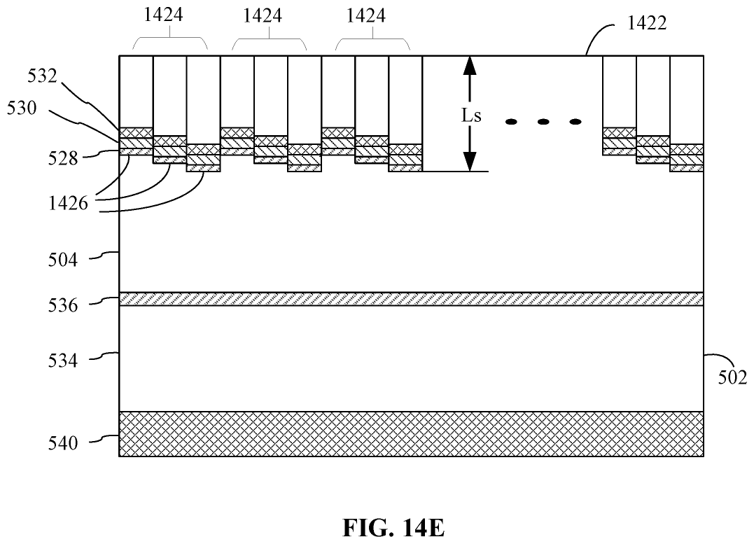

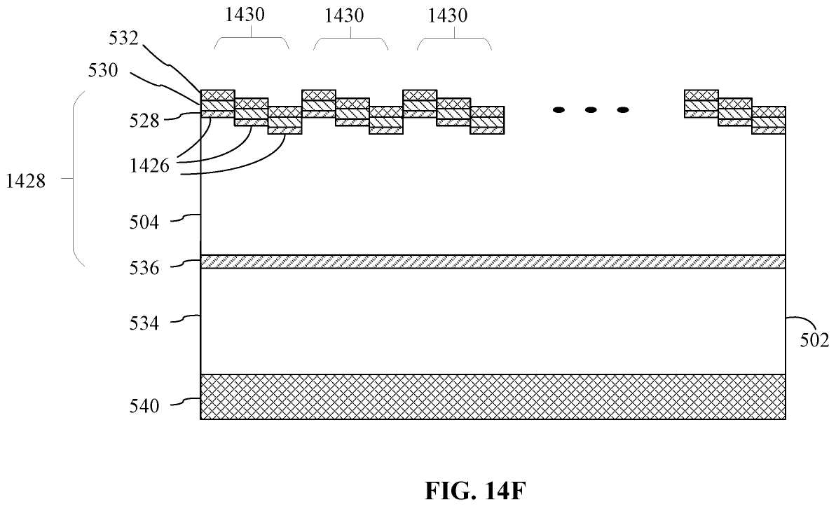

As a non-limiting example, FIG. 14A illustrates mask 1408 that comprises first mask portion 1410, and multiple second mask portion arrays 1414 spatially separated from each other and arranged in a two-dimensional array. Each second mask portion array 1414 comprises an array of second mask portions 1412 spatially separated from each other and arranged in a two-dimensional array. Second mask portion 1412 has first characteristic dimension W″x in the first direction (e.g., x-direction) and second characteristic dimension W″y in the second direction (e.g., y-direction). W″x and W″y can be the same as or different from each other. In some exemplary embodiments, W″x is between 0.1 μm and 1 μm, between 1 μm and 10 μm, between 10 μm and 20 μm, or between 20 μm and 30 μm, and W″y is between 0.1 μm and 1 μm, between 1 μm and 10 μm, between 10 μm and 20 μm, or between 20 μm and 30 μm. In an exemplary embodiment, second mask portion 1412 has a size that matches with a pixel of the detector to be used for detecting the transmitted light. In another exemplary embodiment, second mask portion 1412 has a size that matches with a cluster of pixels of the detector to be used for detecting the transmitted light.

While FIG. 14A illustrates that second mask portion 1412 has a substantially square shape, it should be noted that second mask portion 1412 can have any suitable shapes in the plane perpendicular to the depths (e.g., in the x-y plane) including but not limited to rectangle, circle, oblong, polygon, or the like. While FIG. 14A illustrates second mask portion arrays 1414 being substantially the same as each other, it should be noted that different second mask portion arrays can have different configurations. For instance, different second mask portion arrays can include different numbers of second mask portions.

Block 1306. With reference to block 1304 of FIG. 13, method 1300 includes positioning the substrate and the mask relative to each other at each relative position in an array of relative positions, wherein a distance between two adjacent relative positions along the first direction is equal to i the first dimension of any second mask portion in the array of second mask portions, and a distance between two adjacent relative positions along the second direction is equal to the second dimension of any second mask portion in the array of second mask portions.

This is similar to the positioning of the substrate and the mask disclosed herein with reference to block 606 of method 600, except the relative positions and the number of the relative positions in method 1300 are determined at least in part by the second mask portion array, in particular, by the arrangement of the second mask portions within each second mask portion array. In some exemplary embodiments, the number of relative positions is between 5 and 10, between 10 and 20, between 30 and 40, between 40 and 50, or between 50 and 100. For instance, in some exemplary embodiments, the substrate and the mask are positioned relative to each other at each relative position in a 4×3 array of relative positions.

Block 1306. With reference to block 1306 of FIG. 13, method 1300 includes exposing, at each respective relative position in the array of relative positions, the first polymer layer through the mask to a corresponding dose in an array of doses of the radiation, thereby producing one or more exposed polymer portions in the first polymer layer, wherein each exposed polymer portion comprises an array of dosed units and each dosed unit comprises an array of dosed segments, wherein of each dosed unit, at least two dosed segments are exposed to different doses of the radiation.

For instance, as a non-limiting example, FIG. 14B illustrate exposing first polymer layer 504 exposed through mask 1408 at each respective relative position in the array (e.g., 4×3) of relative positions to a corresponding dose in an array of doses of the radiation. As such, corresponding to each second mask portion array 1414, the exposure produces an exposed polymer portion such as exposed polymer portion 1416 in the first polymer layer. Exposed polymer portion 1416 comprises an array of dosed units such as dosed unit 1418. Each dosed unit comprises an array of dosed segments such as dosed segment 1420. The doses of the radiation are controlled, for instance, by control of the duration and/or intensity, such as of each dosed unit, at least two dosed segments are exposed to different doses of the radiation. In an exemplary embodiment, of each dosed unit of each exposed polymer portion, each dosed segment is exposed to a different dose of the radiation.

Block 1308. With reference to block 1308 of FIG. 13, method 1300 includes developing the first polymer layer of the substrate such that each exposed polymer portion produces a patterned structure, thereby creating one or more patterned structures in the first polymer layer of the substrate. This is similar to the developing of the first polymer layer of the substrate disclosed herein with reference to block 414 of method 400 and with reference to block 610 of method 600. However, unlike in method 400 or method 600 where each patterned structure comprises an array of first surfaces each being unique and different, each patterned structure in method 1300 comprises an array of structure units, each structure unit comprising an array of first surfaces, wherein of each structure unit of each patterned structure, at least two first surfaces are at different depths.

For instance, as a non-limiting example, FIG. 14 illustrates that each exposed polymer portion 1416 in the first polymer layer is developed to produce a patterned structure such as patterned structure 1422, and patterned structure 1422 comprises an array of structure units such as structure unit 1424. Each structure unit 1424 comprises an array of first surfaces such as first surface 1426 illustrated in FIGS. 14D and 14E. Of each structure unit 1424 of each patterned structure 1422, at least two first surfaces are at different depths. In some exemplary embodiments, of each dosed unit of each exposed polymer portion, each dosed segment is exposed to a different dose of the radiation, thereby producing each first surface of each structure unit of each patterned structure at a different depth. As a non-limiting example, FIG. 14D illustrates structure unit 1424 comprising a 4×3 array of first surfaces 1426, each at a different depth Ls.

In some exemplary embodiments, of a respective structure unit such as structure unit 1424, the depths of first surfaces range from 100 nm to 300 nm, from 200 nm to 400 nm, from 300 nm to 500 nm, from 400 nm to 800 nm, from 500 nm to 1000 nm, from 200 nm to 1000 nm, from 200 nm to 1500 nm, from 100 nm to 1500 nm, or from 100 nm to 2000 nm.

After the developing of the first polymer layer of the substrate, method 1300 can include other additional or optional processes. Examples of additional or optional processes include but are not limited to (i) depositing a layer of a first reflective material on top of the one or more patterned structures similar to those disclosed herein with reference to block 416, (ii) overlaying a first protection layer on the layer of the first reflective material similar to those disclosed herein with reference to block 418, (iii) overlaying a second protection layer on the first protection layer similar to those disclosed herein with reference to block 420, (iv) dicing the substrate to produce one or more individual chips similar to those disclosed herein with reference to block 422, (v) attaching a sensor array above or under each of the one or more patterned structures similar to those disclosed herein with reference to block 424, or any practical combination thereof.

As a non-limiting example, FIG. 14E illustrates method 1300 that includes the depositing of first reflective layer 528, the overlaying of first protective layer 530, the overlaying of second protective layer 532, and the attaching of sensor array 540 under patterned structure 1422. In some exemplary embodiments, the substrate comprises a glass substrate coated with a layer of second reflective material such as second reflective layer 536. As such, corresponding to each patterned structure 1422, optical array 1428 (e.g., filter array) is formed by first reflective layer 528, second reflective layer 536 and first polymer layer 504 in-between the first and second reflective layers as illustrated in FIG. 14F. The optical array (e.g., filter array) includes an array of etalon units such as etalon unit 1430, each corresponding to one structure unit (e.g., structure unit 1424). Each etalon unit 1430 comprises an array of etalons formed by the first reflective layer, the second reflective layer and the first polymer layer in-between the first and second reflective layers.

The optical array (e.g., optical array 1428) and sensor array (e.g., sensor array 540) collectively form an optical device that can be used in a variety of applications, including but not limited to multi/hyperspectral imaging.

IV-2. Exemplary Method 1500 and Method 1600

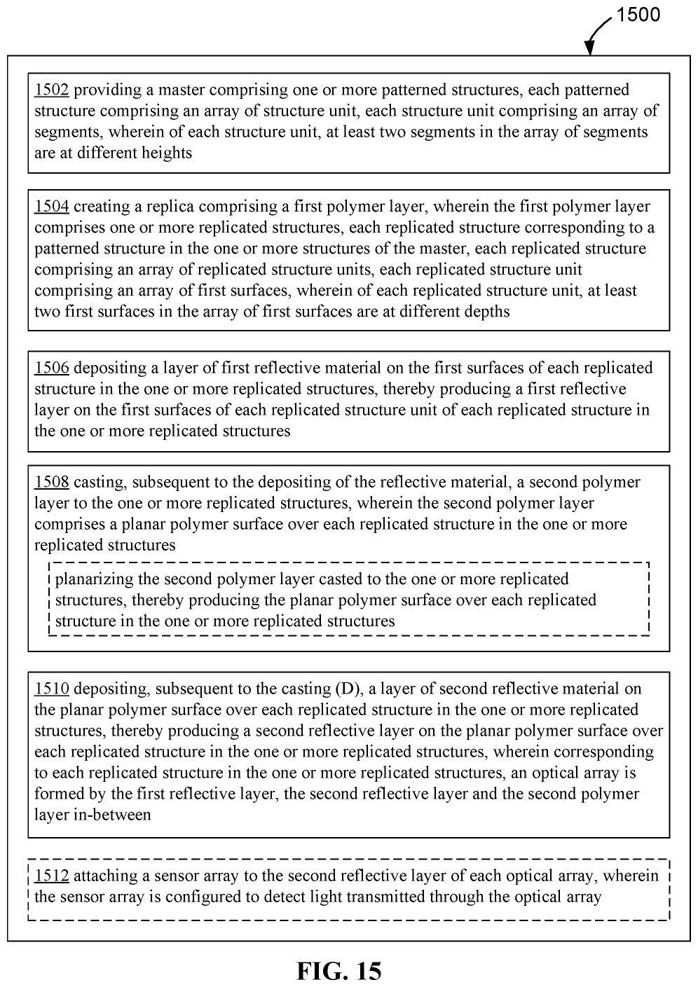

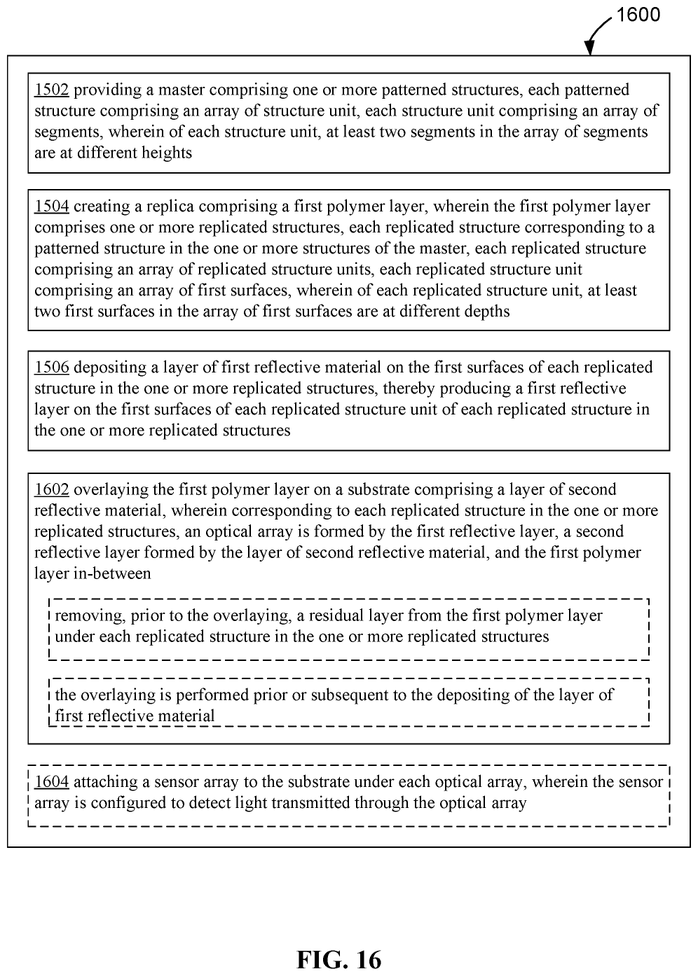

FIG. 15 illustrates a flow chart describing exemplary method 1500 for mass replicating filter arrays with replicated etalon units in accordance with some exemplary embodiments of the present disclosure, and FIG. 16 illustrates a flow chart describing exemplary method 1600 for mass replicating filter arrays with replicated etalon units in accordance with some exemplary embodiments of the present disclosure. In some exemplary embodiments, method 1500 or method 1600 further includes manufacturing the master, for instance by manufacturing a polymer mold (e.g., using method 1300), wherein the polymer mold comprises one or more patterned mold structures in a third polymer layer, wherein each patterned mold structure comprises an array of mold structure unit, each mold structure unit comprising an array of mold surfaces at different depths. In some exemplary embodiments, method 1500 or method 1600 further includes depositing a conductive film over the one or more patterned structures in the third polymer layer of the substrate, and electroplating the conductive film over the one or more patterned structures in the third polymer layer of the substrate with a layer of an electroplating material, thereby producing the master made of the electroplating material. While the configuration of the masters used in method 1500 and method 1600 are different from those in method 800 and method 100, the processes per se are similar. As such, description of the mass replicating of filter arrays and optical devices having filter arrays are omitted herein to avoid redundancy.

It should be noted that blocks disclosed in all flow charts are not necessarily in order. Some processes can be performed either before or after some other processes. For instance, as an example, the positioning of the substrate and the mask disclosed with reference to block 406 and the exposing the first polymer layer disclosed with reference to block 408 can be performed either before or after the positioning of the substrate and the mask disclosed with reference to block 410 and the exposing the first polymer layer disclosed with reference to block 412. As another example, the attaching of a sensor array disclosed with reference to block 422 can be performed either before or after the dicing of the substrate disclosed with reference to block 420.

The methods of the present application have several advantages. For instance, they allow a wide range of patterning field sizes (e.g., the sizes of second mask portions, or second mask portion arrays) from micrometers to centimeters. They allow controllable increment of cavity thicknesses at tens of nanometers. The cavity structures are monolithic (e.g., two reflective layer spaced apart), and thus with enhanced thermal stability. They also enable parallel manufacturing of multiple etalon arrays per wafer in a single lithographic step, and at a short production time (e.g. structuring of about 150 etalon arrays of 60 by 30 cavities each within 3 hours). Further, they make it possible to mass replicate large etalon arrays and filter arrays on a wafer scale via nano-imprinting, thereby eliminating lithography steps. As such, they significantly reduce the production time and cost, and enable large-scale mass production.

The methods of the present application can be implemented as a computer program product that includes a computer program mechanism embedded in a non-transitory computer readable storage medium. For instance, the computer program product could contain program modules comprising instructions for executing any combination of features (e.g., the positioning, the exposing, etc.) shown or described in FIG. 4A-11C and FIGS. 13-16. These program modules can be stored on a CD-ROM, DVD, magnetic disk storage product, USB key, or any other non-transitory computer readable data or program storage product.

The large etalon arrays of the present application and optical devices having such large etalon arrays can be used in various applications including but not limited to optical spectroscopy such as Fabry-Perot spectrometer or reconstructive spectrometry. Also, the filter arrays with replicated etalon units of the present application and optical devices having such filter arrays can be used in various applications including but not limited to multispectral/hyperspectral imaging such as medical imaging devices for disease diagnosis and image-guided surgery.

### REFERENCES CITED AND ALTERNATIVE EMBODIMENTS

All references cited herein are incorporated herein by reference in their entirety and for all purposes to the same extent as if each individual publication or patent or patent application was specifically and individually indicated to be incorporated by reference in its entirety for all purposes.

Many modifications and variations of this invention can be made without departing from its spirit and scope, as will be apparent to those skilled in the art. The specific embodiments described herein are offered by way of example only. The embodiments were chosen and described in order to best explain the principles of the invention and its practical applications, to thereby enable others skilled in the art to best utilize the invention and various embodiments with various modifications as are suited to the particular use contemplated. The invention is to be limited only by the terms of the appended claims, along with the full scope of equivalents to which such claims are entitled.

The terminology used herein is for the purpose of describing particular embodiments only and is not intended to be limiting of the claims. As used in the description of the embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will also be understood that, although the terms first, second, etc. may be used herein to describe various elements, these elements should not be limited by these terms. These terms are only used to distinguish one element from another. For example, a first reflective layer could be termed a second reflective layer, and, similarly, a second reflective layer could be termed a first reflective layer, without departing from the scope of the present invention, so long as all occurrences of the first reflective layer are renamed consistently and all occurrences of the second reflective layer are renamed consistently. The first reflective layer and the second reflective layer are both reflective layers, but they are not the same reflective layer.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

1. A method for manufacturing one or more optical arrays, the method comprising:
(A) providing a substrate comprising a first polymer layer sensitive to a radiation;
(B) providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction;
(C) positioning the substrate and the mask relative to each other at each relative position in a first plurality of relative positions along the first direction, wherein a distance between adjacent relative positions in the first plurality of relative positions is equal to or less than the first dimension of any second mask portion in the one or more second mask portions;
(D) exposing, at each respective relative position in the first plurality of relative positions, the first polymer layer through the mask to a corresponding dose in a first plurality of doses of the radiation, thereby producing one or more first exposed polymer portions in the first polymer layer;
(E) positioning the substrate and the mask relatively to each other at each relative position in a second plurality of relative positions along the second direction, wherein a distance between adjacent relative positions in the second plurality of relative positions is equal to or less than the second dimension of any second mask portion in the one or more second mask portions; and
(F) exposing, at each respective relative position in the second plurality of relative positions, the first polymer layer through the mask to a corresponding dose in a second plurality of doses of the radiation, thereby producing one or more second exposed polymer portions in the first polymer layer;
wherein each respective second exposed polymer portion in the one or more second exposed polymer portions overlaps at least partially with each corresponding first exposed polymer portion in the one or more first portions, thereby producing one or more overlapped exposed polymer portions, each overlapped exposed polymer portion creates an array of dosed segments, wherein each dosed segment in the array of dosed segments is exposed to a different dose of the radiation.

2. The method of claim 1, wherein a distance between any two relative positions in the first plurality of relative positions is equal to or less than the first dimension of any second mask portion in the one or more second mask portions, or a distance between any two relative positions in the second plurality of relative positions is equal to or less than the second dimension of any second mask portion in the one or more second mask portions.

3. A method for manufacturing one or more optical arrays, the method comprising:
(A1) providing a substrate comprising a first polymer layer sensitive to a radiation;
(B1) providing a single mask comprising a first mask portion configured to block the radiation and one or more second mask portions configured to allow the radiation to pass through, wherein each second mask portion in the one or more second mask portions has a first dimension in a first direction and a second dimension in a second direction, wherein the second direction is different from the first direction;
(C1) positioning the substrate and the mask relative to each other at each relative position in an array of relative positions, wherein a distance between two adjacent relative positions along the first direction is equal tom the first dimension of any second mask portion in the one or more second mask portions, and a distance between two adjacent relative positions along the second direction is equal to the second dimension of any second mask portion in the one or more second mask portions; and
(D1) exposing, at each respective relative position in the array of relative positions, the first polymer layer through the mask to a corresponding dose in an array of doses of the radiation, thereby producing one or more final exposed polymer portions in the first polymer layer, each final exposed polymer portion comprising an array of dosed segments, wherein each dosed segment in the array of dosed segments is exposed to a different dose of the radiation.

4. The method of claim 1, further comprising:
(G) developing the first polymer layer of the substrate such that of each overlapped or final exposed polymer portion, each dosed segment in the array of dosed segments is developed to produce a first surface at a different depth in the first polymer layer, thereby creating one or more patterned structures in the first polymer layer of the substrate, each patterned structure comprising an array of first surfaces at different depths.

5. The method of claim 4, wherein of a respective patterned structure in the one or more patterned structures, the depths of the array of first surfaces range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm.

6. The method of claim 4, wherein of a respective patterned structure in the one or more patterned structures, at least two depths of the array of first surfaces differ from each other by at least two orders of magnitude, or by at least three orders of magnitude.

7. The method of claim 4, further comprising:
(H) depositing a layer of a first reflective material on top of the one or more patterned structures.

8. The method of claim 7, wherein the layer of the first reflective material comprises a semi-transparent aluminum film having a thickness of between 5 and 10 nm, between 10 and 15 nm, between 15 and 20 nm, between 20 and 25 nm, or between 25 and 30 nm.

9. The method of claim 7, further comprising:
(I) overlaying a first protection layer on the layer of the first reflective material.

10. The method of claim 9, wherein the first protection layer is made of a material comprising silicon dioxide (SiO2).

11. The method of claim 9, further comprising:
(J) overlaying a second protection layer on the first protection layer.

12. The method of claim 11, wherein the second protection layer is made of a material comprising a polymer.

13. The method of claim 7, further comprising:
(K) dicing the substrate to produce one or more individual chips, each comprising a patterned structure in the one or more patterned structures.

14. The method of claim 7, wherein the substrate comprises a glass substrate coated with a layer of second reflective material, wherein the first polymer layer overlays the layer of second reflective material, wherein corresponding to each of the one or more patterned structures, an optical array is formed by the second reflective layer, a first reflective layer formed by the layer of first reflective material, and the first polymer layer in-between.

15. The method of claim 14, wherein the first polymer layer comprises a Poly(methyl methacrylate) (PMMA) film spun on top of the coated glass substrate.

16. The method of claim 14, wherein the layer of second reflective material comprises a semi-transparent aluminum film having a thickness of between 5 and 10 nm, between 10 and 15 nm, between 15 and 20 nm, between 20 and 25 nm, or between 25 and 30 nm.

17. The method of claim 14, further comprising:
(L) attaching a sensor array above or under each of the one or more patterned structures, wherein the sensor array is configured to detect light transmitted through the optical array, wherein the attaching (L) is performed prior to or subsequent to the dicing (K).

18. The method of claim 1, wherein the radiation comprises an X-ray beam, or a UV beam.

19. The method of claim 1, wherein the first polymer layer has a thickness between 2 and 5 μm, between 5 and 10 μm, between 10 and 15 μm, between 15 and 20 μm, between 20 and 30 μm, between 30 and 50 μm, or between 50 and 100 μm.

20. The method of claim 1, wherein the first and second directions are substantially perpendicular to each other.

21. The method of claim 1, wherein each second mask portion in the one or more second mask portions has characteristic dimensions of between 0.001×0.001 and 0.1×0.1 mm², between 1×1 and 1.5×1.5 mm², between 1.5×1.5 and 2×2 mm², between 2×2 and 2.5×2.5 mm², or between 2.5×2.5 and 3×3 mm².

22. The method of claim 1, wherein the one or more second mask portions comprises between 10 and 50 second mask portions, between 50 and 100 second mask portions, between 100 and 150 second mask portions, between 150 and 200 second mask portions, between 200 and 300 second mask portions, between 300 and 400 second mask portions, or between 400 and 500 second mask portions, or between 1000 and 100000 second mask portions wherein each second mask portion is spatially separated from another.

23. The method of claim 22, wherein at least two second mask portions have a same configuration.

24. The method of claim 22, wherein at least two second mask portions have different configurations.

25. The method of claim 1, wherein the first relative position in the second plurality of relative positions coincides with the first relative position in the first plurality of relative positions.

26. The method of claim 1, wherein the positioning (C) is performed stepwise and successively along the first direction.

27. The method of claim 1, wherein the positioning (E) is performed stepwise and successively along the second direction.

28. The method of claim 1, wherein the positioning (E) is performed prior to or subsequent to the positioning (C).

29. The method of claim 1, wherein at least two first distances are the same as each other, wherein a first distance is a distance between two adjacent relative positions in the first plurality of relative positions.

30. The method of claim 1, wherein at least two first distances are different from each other, wherein a first distance is a distance between two adjacent relative positions in the first plurality of relative positions.

31. The method of claim 1, wherein at least two second distances are the same as each other, wherein a second distance is a distance between two adjacent relative positions in the second plurality of relative positions.

32. The method of claim 1, wherein at least two second distances are different from each other, wherein a second distance is a distance between two adjacent relative positions in the second plurality of relative positions.

33. The method of claim 1, wherein at least two doses in the first plurality of doses are the same as each other.

34. The method of claim 1, wherein at least two doses in the first plurality of doses are different from each other.

35. The method of claim 1, wherein at least two doses in the second plurality of doses are the same as each other.

36. The method of claim 1, wherein at least two doses in the second plurality of doses are different from each other.

37. The method of claim 1, wherein the first plurality of relative positions along the first direction comprises between 10 and 200 relative positions, between 200 and 500 relative positions, or between 500 and 1000 relative positions.

38. The method of claim 1, wherein the second plurality of relative positions along the first direction comprises between 10 and 200 relative positions, between 200 and 500 relative positions, or between 500 and 1000 relative positions.

39. A method for one or more optical arrays, the method comprising:
(A) providing a master comprising one or more patterned structures, each patterned structure comprising an array of segments at different heights;
(B) creating a replica comprising a first polymer layer, wherein the first polymer layer comprises one or more replicated structures, each replicated structure corresponding to a patterned structure in the one or more structures of the master, each replicated structure comprising an array of first surfaces at different depths corresponding to the array of segments at different heights;
(C) depositing a layer of first reflective material on the first surfaces of each replicated structure in the one or more replicated structures, thereby producing a first reflective layer on the first surfaces of each replicated structure in the one or more replicated structures;
(D) casting, subsequent to the depositing (C), a second polymer layer to the one or more replicated structures, wherein the second polymer layer comprises a planar polymer surface over each replicated structure in the one or more replicated structures; and
(E) depositing, subsequent to the casting (D), a layer of second reflective material on the planar polymer surface over each replicated structure in the one or more replicated structures, thereby producing a second reflective layer on the planar polymer surface over each replicated structure in the one or more replicated structures;
wherein corresponding to each replicated structure in the one or more replicated structures, an optical array is formed by the first reflective layer, the second reflective layer and the second polymer layer in-between.

40. The method of claim 39, further comprising:
planarizing, subsequent to the casting (D) and prior to the depositing (E), the second polymer layer casted to the one or more replicated structures, thereby producing the planar polymer surface over each replicated structure in the one or more replicated structures.

41. The method of claim 40, wherein the planarizing is performed by chemical polishing, mechanical polishing, plasma etching, or any combination thereof.

42. The method of claim 39, further comprising:
attaching a sensor array to the second reflective layer of each optical array, wherein the sensor array is configured to detect light transmitted through the optical array.

43. The method of claim 42, wherein the sensor array is glued to the second reflective layer by an adhesive.

44. The method of claim 42, wherein the sensor array comprises a photon detector, a thermal detector, or any combination thereof.

45. The method of claim 44, wherein the photon detector comprises a charge-coupled device (CCD), a complementary metal-oxide semiconductor (CMOS), an Indium Gallium Arsenide (InGaAs) photodiode detector, a Germanium (Ge) photodiode detector, a Mercury Cadmium Telluride (MCT) array, or any combination thereof.

46. The method of claim 44, wherein the thermal detector comprises a microbolometer array, a microthermocouple array, or any combination thereof.

47. A method, comprising:
(A) providing a master comprising one or more patterned structures, each patterned structure comprising an array of segments at different heights;
(B) creating a replica comprising a first polymer layer, wherein the first polymer layer comprises one or more replicated structures, each replicated structure corresponding to a patterned structure in the one or more structures of the master, each replicated structure comprising an array of first surfaces at different depths corresponding to the array of segments at different heights;
(C) depositing a layer of first reflective material on the first surfaces of each replicated structure in the one or more replicated structures, thereby producing a first reflective layer on the first surfaces of each replicated structure in the one or more replicated structures; and
(D) overlaying the first polymer layer on a substrate comprising a layer of second reflective material;
wherein corresponding to each replicated structure in the one or more replicated structures, an optical array is formed by the first reflective layer, a second reflective layer formed by the layer of second reflective material, and the first polymer layer in-between.

48. The method of claim 47, wherein the overlaying (D) is performed prior or subsequent to the depositing (C).

49. The method of claim 47, wherein the substrate comprises a glass substrate, wherein the glass substrate is coated with the layer of second reflective material.

50. The method of claim 47, wherein the first polymer layer is glued to the layer of second reflective material.

51. The method of claim 47, further comprising:
removing, prior to the overlaying (D), a residual layer from the first polymer layer under each replicated structure in the one or more replicated structures,

52. The method of claim 51, wherein the removing (E) is performed by reactive-ion etching.

53. The method of claim 47, further comprising:
attaching a sensor array to the substrate under each optical array, wherein the sensor array is configured to detect light transmitted through the optical array.

54. The method of claim 53, wherein the sensor array is glued to the substrate by an adhesive.

55. The method of claim 53, wherein the sensor array comprises a charge-coupled device (CCD), a complementary metal-oxide semiconductor (CMOS), an Indium Gallium Arsenide (InGaAs) photodiode detector, a Germanium (Ge) photodiode detector, a Mercury Cadmium Telluride (MCT) array, a microbolometer array, a microthermocouple array, or any combination thereof.

56. The method of claim 39, further comprising:
manufacturing a polymer mold, wherein the polymer mold comprises one or more patterned mold structures in a third polymer layer, wherein each patterned mold structure comprises an array of mold surfaces at different depths;
depositing a conductive film over the one or more patterned molded structures in the third polymer layer; and
electroplating the conductive film over the one or more patterned mold structures in the third polymer layer with a layer of an electroplating material, thereby producing the master made of the electroplating material.

57. The method of claim 56, wherein the electroplating material comprises nickel.

58. The method of claim 39, wherein the first or second reflective material comprises aluminum.

59. The method of claim 39, wherein of a respective replicated structure in the one or more replicated structures, the depths of the array of first surfaces range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm

60. The method of claim 59, wherein of a respective replicated structure in the one or more replicated structures, at least two depths of the array of first surfaces differ from each other by at least two orders of magnitude, or by at least three orders of magnitude.

61. The method of claim 39, wherein of a respective replicated structure in the one or more replicated structures, the array of first surfaces comprises N×M first surfaces, wherein M is any integer between 1 and 5000, and N is any integer between 1 and 5000.

62. A method for manufacturing one or more filter arrays each with replicated units, the method comprising:
(A) providing a substrate comprising a first polymer layer sensitive to a radiation;
(B) providing a single mask comprising a first mask portion and one or more second mask portion arrays, wherein the first mask portion is configured to block the radiation, and each second mask portion array in the one or more second mask portion arrays comprises an array of second mask portions configured to allow the radiation to pass through, wherein each second mask portion in the array of second mask portions has a first dimension in a first direction and a second dimension in a second direction, wherein the second direction is different from the first direction;
(C) positioning the substrate and the mask relative to each other at each relative position in an array of relative positions, wherein a distance between two adjacent relative positions along the first direction is equal to in the first dimension of any second mask portion in the array of second mask portions, and a distance between two adjacent relative positions along the second direction is equal to the second dimension of any second mask portion in the array of second mask portions; and
(D) exposing, at each respective relative position in the array of relative positions, the first polymer layer through the mask to a corresponding dose in an array of doses of the radiation, thereby producing one or more exposed polymer portions in the first polymer layer, wherein each exposed polymer portion comprises an array of dosed units and each dosed unit comprises an array of dosed segments, wherein of each dosed unit, at least two dosed segments are exposed to different doses of the radiation.

63. The method of claim 62, wherein the positioning (C) is performed stepwise.

64. The method of claim 62, further comprising:
(E) developing the first polymer layer of the substrate such that each exposed polymer portion produces a patterned structure, thereby creating one or more patterned structures in the first polymer layer of the substrate, wherein each patterned structure comprises an array of structure units, each structure unit comprising an array of first surfaces, wherein of each structure unit of each patterned structure, at least two first surfaces are at different depths.

65. The method of claim 64, wherein of each dosed unit of each exposed polymer portion, each dosed segment is exposed to a different dose of the radiation, thereby producing each first surface of each structure unit of each patterned structure at a different depth.

66. The method of claim 64, wherein of a respective structure unit, the depths of the array of first surfaces range from 100 nm to 300 nm, from 200 nm to 400 nm, from 300 nm to 500 nm, from 400 nm to 800 nm, from 500 nm to 1000 nm, from 200 nm to 1000 nm, from 200 nm to 1500 nm, from 100 nm to 1500 nm, or from 100 nm to 2000 nm.

67. The method of claim 64, further comprising:
(F) depositing a layer of a first reflective material on top of the one or more patterned structures.

68. The method of claim 67, further comprising:
(G) overlaying a first protection layer on the layer of the first reflective material.

69. The method of claim 68, further comprising:
(H) overlaying a second protection layer on the first protection layer.

70. The method of claim 67, further comprising:
(I) dicing the substrate to produce one or more individual chips, each comprising a patterned structure in the one or more patterned structures.

71. The method of claim 67, wherein the substrate comprises a glass substrate coated with a layer of second reflective material, wherein the first polymer layer overlays the layer of second reflective material, wherein corresponding to each of the one or more patterned structures, an optical array is formed by the second reflective layer, a first reflective layer formed by the layer of first reflective material, and the first polymer layer in-between.

72. The method of claim 71, further comprising:
(J) attaching a sensor array to the layer of the second reflective material above each of the one or more patterned structures or to the substrate under each of the one or more patterned structures, wherein the sensor array is configured to detect light transmitted through the optical array, wherein the attaching is performed prior to or subsequent to the dicing (I).

73. The method of claim 62, wherein the one or more second mask portion arrays comprises a number of second mask portion arrays that is between 10 and 50, between 50 and 100, between 100 and 150, between 150 and 200, between 200 and 300, between 300 and 400, or between 400 and 500, wherein each second mask portion array is spatially separated from another.

74. The method of claim 62, wherein a second mask portion array in the one or more second mask portion arrays comprises a number of second mask portions that is between 10 and 100, between 100 and 200, between 200 and 500, between 500 and 1000, between 1000 and 2000, between 2000 and 5000, or between 5000 and 10000, wherein each second mask portion is spatially separated from another.

75. The method of claim 62, wherein the array of relative positions is a 1-dimensional or 2-dimensional array, and comprises a number of relative positions that is between 3 and 10, between 10 and 20, between 20 and 50, between 50 and 100, or between 100 and 1000.

76. The method of claim 62, wherein each second mask portion has characteristic dimensions of between 0.1×0.1 μm² and 1×1 μm², between 1×1 μm² and 10×10 μm², between 10×10 μm² and 20×20 μm², or between 20×20 μm² and 30×30 μm².

77. A method for mass replicating one or more filter arrays each with replicated units, the method comprising:
(A) providing a master comprising one or more patterned structures, each patterned structure comprising an array of structure unit, each structure unit comprising an array of segments, wherein of each structure unit, at least two segments in the array of segments are at different heights;
(B) creating a replica comprising a first polymer layer, wherein the first polymer layer comprises one or more replicated structures, each replicated structure corresponding to a patterned structure in the one or more structures of the master, each replicated structure comprising an array of replicated structure units, each replicated structure unit comprising an array of first surfaces, wherein of each replicated structure unit, at least two first surfaces in the array of first surfaces are at different depths;
(C) depositing a layer of first reflective material on the first surfaces of each replicated structure in the one or more replicated structures, thereby producing a first reflective layer on the first surfaces of each replicated structure unit of each replicated structure in the one or more replicated structures;
(D) casting, subsequent to the depositing (C), a second polymer layer to the one or more replicated structures, wherein the second polymer layer comprises a planar polymer surface over each replicated structure in the one or more replicated structures; and
(E) depositing, subsequent to the casting (D), a layer of second reflective material on the planar polymer surface over each replicated structure in the one or more replicated structures, thereby producing a second reflective layer on the planar polymer surface over each replicated structure in the one or more replicated structures;
wherein corresponding to each replicated structure in the one or more replicated structures, an optical array is formed by the first reflective layer, the second reflective layer and the second polymer layer in-between.

78. The method of claim 77, further comprising:
planarizing, subsequent to the casting (D) and prior to the depositing (E), the second polymer layer casted to the one or more replicated structures, thereby producing the planar polymer surface over each replicated structure in the one or more replicated structures.

79. The method of claim 77, further comprising:
attaching a sensor array to the second reflective layer of each optical array, wherein the sensor array is configured to detect light transmitted through the optical array.

80. A method for mass replicating one or more filter arrays each with replicated units, the method comprising:
(A) providing a master comprising one or more patterned structures, each patterned structure comprising an array of structure unit, each structure unit comprising an array of segments, wherein of each structure unit, at least two segments in the array of segments are at different heights;
(B) creating a replica comprising a first polymer layer, wherein the first polymer layer comprises one or more replicated structures, each replicated structure corresponding to a patterned structure in the one or more structures of the master, each replicated structure comprising an array of replicated structure units, each replicated structure unit comprising an array of first surfaces, wherein of each replicated structure unit, at least two first surfaces in the array of first surfaces are at different depths;
(C) depositing a layer of first reflective material on the first surfaces of each replicated structure in the one or more replicated structures, thereby producing a first reflective layer on the first surfaces of each replicated structure unit of each replicated structure in the one or more replicated structures; and
(D) overlaying the first polymer layer on a substrate comprising a layer of second reflective material;
wherein corresponding to each replicated structure in the one or more replicated structures, an optical array is formed by the first reflective layer, a second reflective layer formed by the layer of second reflective material, and the first polymer layer in-between.

81. The method of claim 80, wherein the overlaying (D) is performed prior or subsequent to the depositing (C).

82. The method of claim 80, further comprising:
removing, prior to the overlaying (D), a residual layer from the first polymer layer under each replicated structure in the one or more replicated structures.

83. The method of claim 80, further comprising:
attaching a sensor array to the substrate under each optical array, wherein the sensor array is configured to detect light transmitted through the optical array.

84. The method of claim 77, further comprising:
manufacturing a polymer mold, wherein the polymer mold comprises one or more patterned mold structures in a third polymer layer, wherein each patterned mold structure comprises an array of mold structure unit, each mold structure unit comprising an array of mold surfaces at different depths;
depositing a conductive film over the one or more patterned molded structures in the third polymer layer; and
electroplating the conductive film over the one or more patterned mold structures in the third polymer layer with a layer of an electroplating material, thereby producing the master made of the electroplating material.

85. An optical array comprising:
at least 1000 etalons, each having a different depth and configured to generate a different transmission pattern when impinged by a light, such that the optical array enables recovery of both narrow and wide spectral bands at high spectral resolutions.

86. The optical array of claim 85, wherein the multiple modes comprise a Fabry-Perot interferometer mode and a reconstructive spectroscopy mode.

87. The optical array of claim 85, wherein the narrow and wide spectral bands are within a spectrum ranging from 200 to 2500 nm.

88. The optical array of claim 85, wherein the depths of at least two etalons in the optical array differ from each other by at least two orders of magnitude, or by at least three orders of magnitude.

89. The optical array of claim 85, wherein the depths of the array of etalons range from 0 to 2 μm, from 0 to 5 μm, from 0 to 10 μm, from 0 to 15 μm, from 0 to 20 μm, from 0 to 25 μm, from 0 to 30 μm, from 0 to 50 μm, or from 0 to 100 μm.

90. The optical array of claim 85, wherein the at least 1000 etalons are arranged as an N×M array, wherein M is any integer between 1 and 5000, and N is any integer between 1 and 5000.

91. An optical array comprising:
an array of etalons, each etalon having a different depth and configured to generate a different transmission pattern when impinged by a light, wherein the depths of at least two etalons in the array differ from each other by two to three orders of magnitude, such that the optical array enables recovery of both narrow and wide spectral bands at high spectral resolutions.

92. The optical array of claim 91, wherein the multiple modes comprise a Fabry-Perot interferometer mode and a reconstructive spectroscopy mode, and the spectrum of light ranges from 200 to 25000 nm.

93. (canceled)

94. (canceled)
